(19) United States
(12) Patent Application Publication
(10) Pub. No.: US 2025/0201658 A1
(43) Pub. Date: Jun. 19, 2025

(54) PACKAGE STRUCTURE AND METHOD FOR FORMING THE SAME

(71) Applicant: Taiwan Semiconductor Manufacturing Company, Ltd., Hsinchu (TW)

(72) Inventors: Kuan-Min Wang, Hsinchu City (TW); Chien-Chang Wang, Hsinchu City (TW); Bang-Li Wu, Hsinchu City (TW); Kuo-Chin Chang, Chiayi City (TW); Kathy Wei Yan, Hsinchu (TW); Jun He, Zhubei City (TW)

(21) Appl. No.: 18/624,484

(22) Filed: Apr. 2, 2024

Related U.S. Application Data
(60) Provisional application No. 63/611,958, filed on Dec. 19, 2023.

(51) Int. Cl. H01L 23/373; H01L 23/00; H01L 23/498; H01L 25/065

(52) U.S. Cl. CPC H01L 23/3735; H01L 23/49816; H01L 24/05; H01L 24/29; H01L 25/0652; H01L 2224/05009; H01L 2224/05025; H01L 2224/29021; H01L 2224/2929; H01L 2924/01013; H01L 2924/01029; H01L 2924/1431; H01L 2924/1434; H01L 2924/15311; H01L 2924/18161

(57) ABSTRACT

A package structure and method for forming the same are provided. The package structure includes a first die formed over a substrate, and a lid structure formed over the first die. The package structure also includes a thermal interface material structure between the first die and the lid structure. The thermal interface material structure includes a plurality of first protruding structures connected to the first die, a plurality of second protruding structures connected to the lid structure and a thermal conductivity material between the first protruding structures and the second protruding structures.

### CROSS REFERENCE TO RELATED APPLICATIONS

This application claims the benefit of U.S. Provisional Application No. 63/611,958, filed on Dec. 19, 2023, the entirety of which is incorporated by reference herein.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

New packaging technologies, such as package on package (POP), have begun to be developed, in which a top package with a device die is bonded to a bottom package, with another device die. By adopting the new packaging technologies, various packages with different or similar functions may be integrated together.

Although existing package structures and methods of fabricating package structure have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1I show cross-sectional representations of various stages of forming a package structure, in accordance with some embodiments of the disclosure.

FIG. 2 shows a cross-sectional representation of a package structure, in accordance with some embodiments of the disclosure.

FIG. 3 shows a cross-sectional representation of a package structure, in accordance with some embodiments of the disclosure.

FIG. 4 shows a cross-sectional representation of a package structure, in accordance with some embodiments of the disclosure.

FIG. 5 shows a cross-sectional representation of a package structure, in accordance with some embodiments of the disclosure.

FIGS. 6A-6C show cross-sectional representations of various stages of forming a package structure, in accordance with some embodiments of the disclosure.

FIGS. 7A-7H show cross-sectional representations of various stages of forming a package structure, in accordance with some embodiments of the disclosure.

FIG. 8 shows a cross-sectional representation of a package structure, in accordance with some embodiments of the disclosure.

FIG. 9 shows a cross-sectional representation of a package structure, in accordance with some embodiments of the disclosure.

FIG. 10 shows a cross-sectional representation of a package structure, in accordance with some embodiments of the disclosure.

FIG. 11 shows a cross-sectional representation of a package structure, in accordance with some embodiments of the disclosure.

FIG. 12 shows a cross-sectional representation of a package structure, in accordance with some embodiments of the disclosure.

FIG. 13A-13C show cross-sectional representations of various stages of forming a package structure, in accordance with some embodiments of the disclosure.

FIG. 14A-14C show cross-sectional representations of various stages of forming a package structure, in accordance with some embodiments of the disclosure.

FIG. 15 shows a cross-sectional representation of a package structure, in accordance with some embodiments of the disclosure.

FIGS. 16A-16F show cross-sectional representations of various stages of forming a package structure, in accordance with some embodiments of the disclosure.

FIG. 17 shows a cross-sectional representation of a package structure, in accordance with some embodiments of the disclosure.

FIG. 18 shows a cross-sectional representation of a package structure, in accordance with some embodiments of the disclosure.

FIGS. 19A-19F show the top views of the protruding structures, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments for a package structure and method for forming the same are provided. The package structure includes a die formed over a substrate. Protruding structures are formed on and thermally connected to the die. A lid structure with additional protruding structures is provided, and the additional protruding structures are formed below and thermally connected to the lid structure. The lid structure is disposed over the die, and a thermal interface material (TIM) structure is constructed by the protruding structures formed on the die and the additional protruding structures formed below the lid structure. The heat or thermal energy generated by the die can be transferred to the external environment by the protruding structures and the additional protruding structures in the thermal interface material (TIM) structure. The stacked alternating protruding structures and additional protruding structures in the thermal interface material (TIM) structure are configured to improve the heat dissipation efficiency. Therefore, the power efficiency and the performance of the package structure are increased.

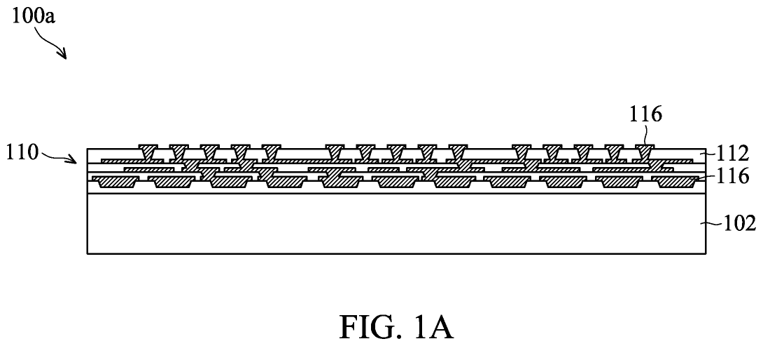

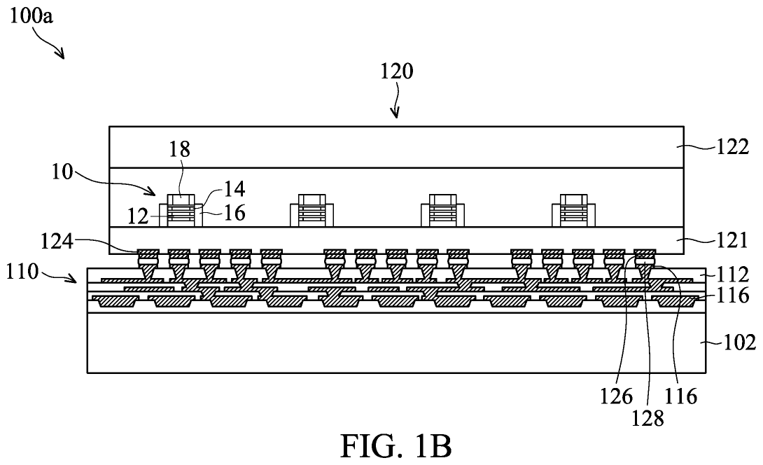

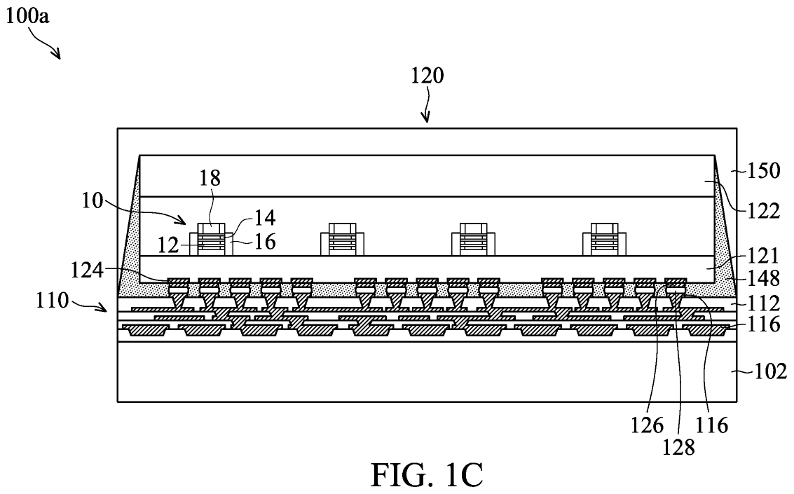

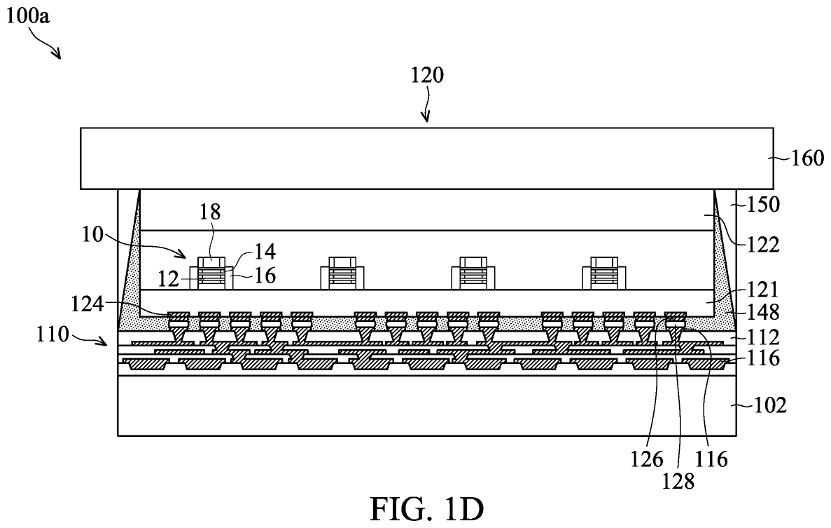

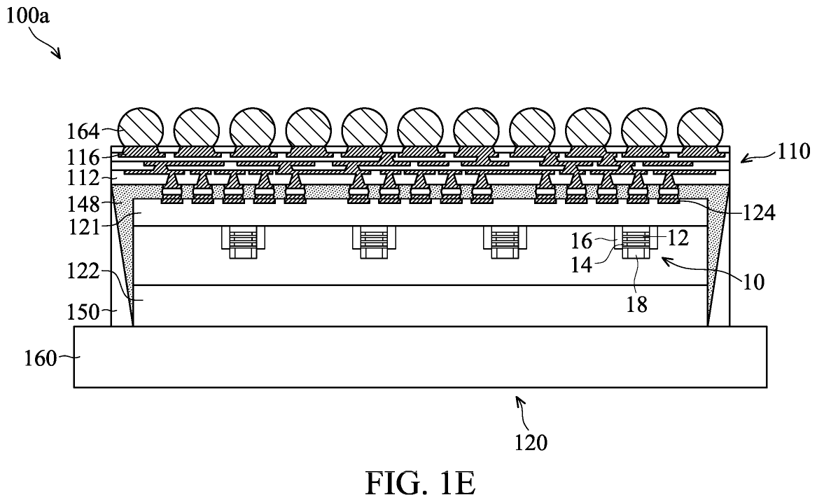

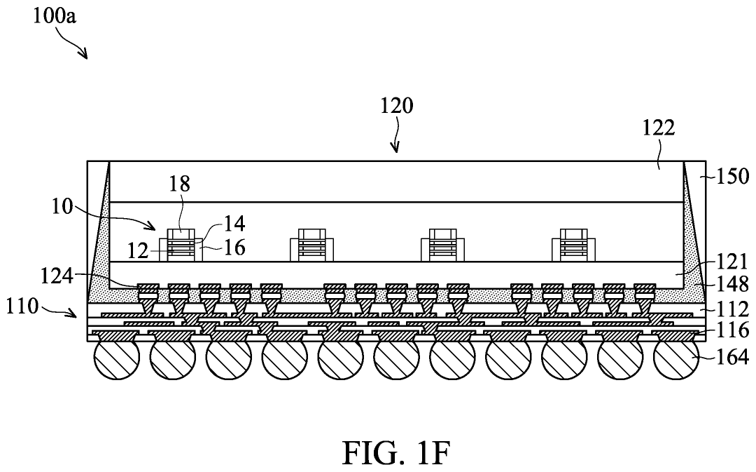

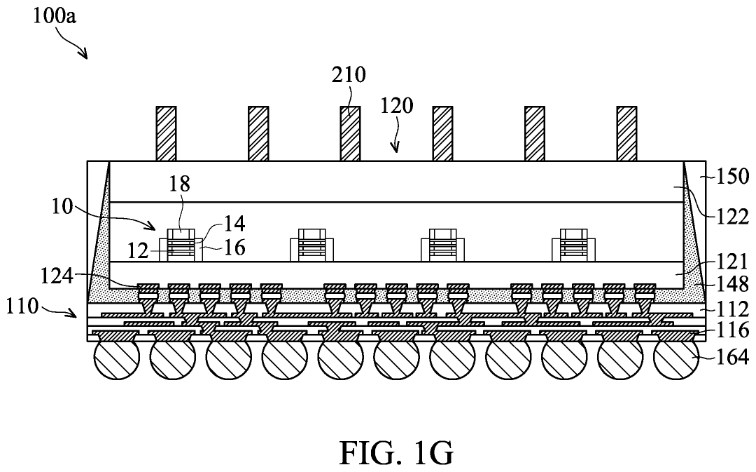

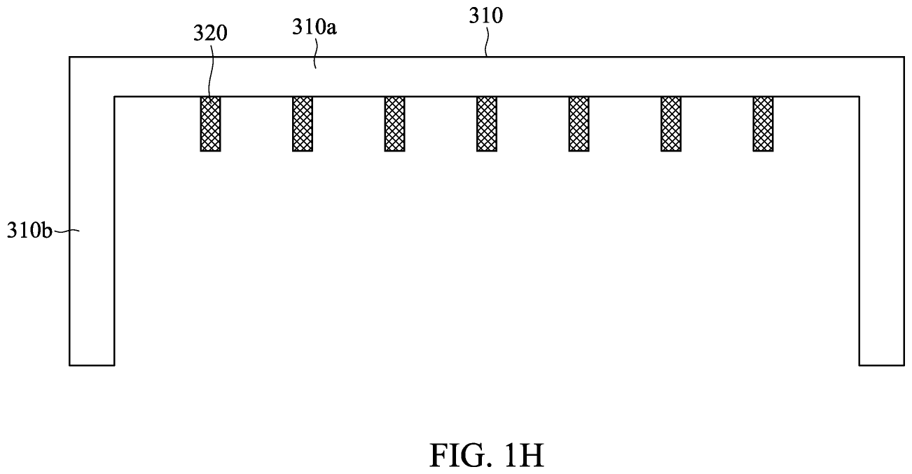

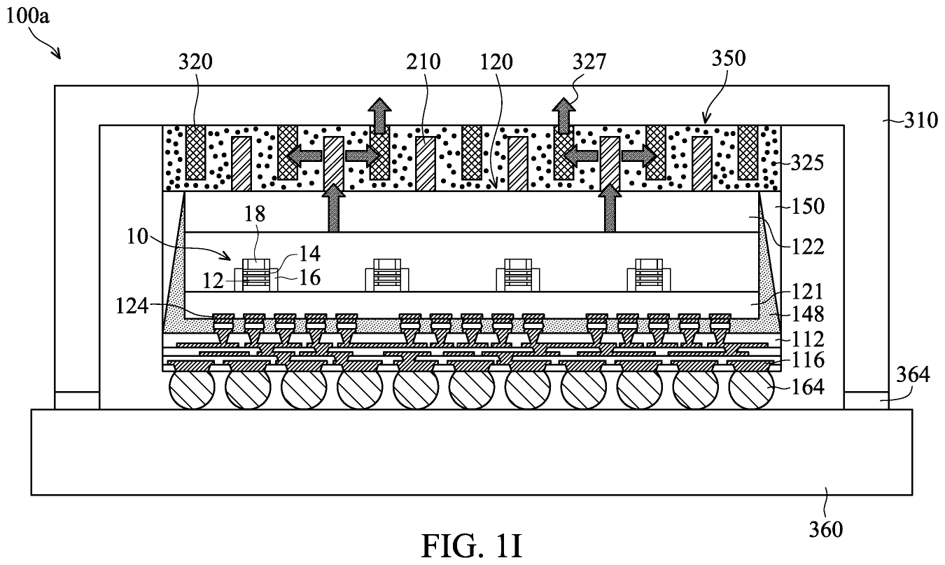

FIGS. 1A-1I show cross-sectional representations of various stages of forming a package structure 100a, in accordance with some embodiments of the disclosure.

Referring to FIG. 1A, a carrier substrate 102 is provided. The carrier substrate 102 is configured to provide temporary mechanical and structural support during subsequent processing steps, in accordance with some embodiments. The carrier substrate 102 includes glass, silicon oxide, aluminum oxide, metal, a combination thereof, and/or the like, in accordance with some embodiments. The carrier substrate 102 includes a metal frame, in accordance with some embodiments.

An interconnect structure 110 is formed over the carrier substrate 102. The interconnect structure 110 may be used as a redistribution (RDL) structure for routing. The interconnect structure 110 includes multiple dielectric layers 112 and multiple conductive layers 116. In some embodiments, some of the conductive layers 116 are exposed at or protruding from the top surface of the top of the dielectric layers 112. The exposed or protruding conductive layers 116 may serve as bonding pads where conductive bumps (such as tin-containing solder bumps) and/or conductive pillars (such as copper pillars) will be formed later.

The dielectric layers 112 may be made of or include one or more polymer materials. The polymer material(s) may include polybenzoxazole (PBO), polyimide (PI), one or more other suitable polymer materials, or a combination thereof. In some embodiments, the polymer material is photosensitive. In some embodiments, some or all of the dielectric layers 112 are made of or include dielectric materials other than polymer materials. The dielectric material may include silicon oxide, silicon carbide, silicon nitride, silicon oxynitride, one or more other suitable materials, or a combination thereof.

Afterwards, as shown in FIG. 1B, a semiconductor die 120 is formed over the carrier substrate 102, in accordance with some embodiments of the disclosure.

The semiconductor die 120 is sawed from a wafer, and may be a “known-good-die”. The semiconductor die 120 may be a system-on-chip (SoC) chip. In some other embodiments, the semiconductor die 120 is a system on integrated circuit (SoIC) device that includes two or more chips with integrated function. The semiconductor die 120 is disposed over the interconnection structure 110.

The semiconductor die 120 has a substrate 121, a semiconductor structure 10 formed on the substrate 102, and a substrate 122 formed on the semiconductor structure 10. In some embodiments, the semiconductor structure 10 is a logic device. For example, in some embodiments the semiconductor structure 10 may be or include a FinFET device, a planar FET, and/or the like. In some embodiments, the semiconductor structure 10 is a gate all around (GAA) transistor structure. In such embodiments, the semiconductor structure 10 includes nanostructures 12 (or called channel layers) formed over the substrate 121, the inner spacer layers 14, the source/drain (S/D) structures 16, and the gate structure 18. The inner spacer layers 14 are between the nanostructures 12 and the S/D structures 16. The source/drain (S/D) structures or region(s) may refer to a source or a drain, individually or collectively dependent upon the context.

In some embodiments, the nanostructures 12 are made of semiconductor materials, such as Si or SiGe. In some embodiments, the inner spacer layers 14 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the S/D structures 16 are made of any applicable material, such as Ge, Si, GaAs, AlGaAs, SiGe, GaAsP, SiP, SiC, SiCP, or a combination thereof.

The gate structure 18 includes a gate dielectric layer and a gate electrode layer. The nanostructures 12 are surrounded by (e.g. wrapped in) the gate dielectric layer. In some embodiments, the gate dielectric layer includes one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the gate electrode layer includes one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof.

The substrate 121 and the substrate 122 may be a semiconductor die or wafer such as a silicon die or wafer. Alternatively or additionally, the substrate 121 and the substrate 122 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP. In some embodiments, the substrate 121 and the substrate 122 are made of silicon (Si).

In some embodiments, a number of conductive pads 124 are formed below the semiconductor die 120, and each of the conductive pads 124 is bonded to the conductive layer 126. Each of the conductive layers 126 is bonded to each of the conductive layers 116 through a number of conductive connectors 128.

The conductive pads 124 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive pad 124 is formed by an electroplating, electroless plating, printing, chemical vapor deposition (CVD) process or physical vapor deposition (PVD) process.

The conductive layers 126 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive layers 126 are formed by an electroplating, electroless plating, printing, a chemical vapor deposition (CVD) process, and/or a physical vapor deposition (PVD) process.

The conductive connector 128 is made of solder materials, such as tin (Sn), tin-silver (SnAg), tin-lead (SnPb), tin-copper (SnCu), tin-silver-copper (SnAgCu), tin-silver-zinc (SnAgZn), tin-zinc (SnZn), tin-bismuth-indium (SnBiIn), tin-indium (SnIn), tin-gold (SnAu), tin-zinc-indium (SnZnIn), tin-silver-Antimony (SnAgSb) or another applicable material. In some embodiments, the conductive connectors 128 are formed by electroplating, electroless plating, printing, a chemical vapor deposition (CVD) process, and/or a physical vapor deposition (PVD) process.

Afterwards, as shown in FIG. 1C, an underfill layer 148 is formed between the semiconductor die 120 and the interconnect structure 110, in accordance with some embodiments of the disclosure. The underfill layer 148 surrounds and protects the conductive layers 126 and the conductive connectors 128. In some embodiments, the underfill layer 148 is in direct contact with the conductive layers 126 and the conductive connectors 128.

In some embodiments, the underfill layer 148 is made of or includes a polymer material. The underfill layer 148 may include an epoxy-based resin. In some embodiments, the underfill layer 148 includes fillers dispersed in the epoxy-based resin.

In some embodiments, the formation of the underfill layer 148 involves an injecting process, a spin-on process, a dispensing process, a film lamination process, an application process, one or more other applicable processes, or a combination thereof. In some embodiments, a thermal curing process is used during the formation of the underfill layer 148.

Afterwards, a package layer 150 is formed over the underfill layer 148. The package layer 150 is also formed over the substrate 122. There is an interface between the underfill layer 148 and the package layer 150, and the interface is lower than the top surface of the semiconductor die 120.

The package layer 150 surrounds and protects the semiconductor die 120. In some embodiments, the package layer 150 is in direct contact with a portion of the semiconductor die 120.

The package layer 150 is made of a molding compound material. The molding compound material may include a polymer material, such as an epoxy-based resin with fillers dispersed therein. In some embodiments, a liquid molding compound material is applied over the semiconductor die 120. A thermal process is then used to cure the liquid molding compound material and to transform it into the package layer 150.

Afterwards, as shown in FIG. 1D, a portion of the package layer 150 is removed to expose the top surface of the substrate 122 of the semiconductor die 120, in accordance with some embodiments of the disclosure. In some embodiments, the portion of the package layer 150 is removed by a planarization process, such as a chemical mechanical polishing (CMP) process.

Afterwards, a carrier substrate 160 is formed over the substrate 122 of the semiconductor die 120 and the package layer 150, in accordance with some embodiments of the disclosure.

The carrier substrate 160 is used as a temporary substrate. The carrier substrate 160 provides mechanical and structural support during subsequent processing steps, such as those described in more detail later. In some embodiments, the substrate 122 of the semiconductor die 120 is adhered to the carrier substrate 160. For example, the substrate 122 and the package layer 150 are attached to the carrier substrate 160 through an adhesive layer (not shown). The adhesive layer is used as a temporary adhesive layer.

Afterwards, as shown in FIG. 1E, the structure as shown in FIG. 1D is flipped and the carrier substrate 102 is removed, in accordance with some embodiments of the disclosure. Next, a portion of conductive layer 116 of the interconnect structure 110 is removed, in accordance with some embodiments of the disclosure. As a result, the conductive layer 116 of the interconnect structure 110 is exposed.

Afterwards, a number of the conductive connectors 164 are formed over the exposed conductive layer 116 of the interconnect structure 110. The conductive connectors 164 are electrically connected to the conductive layers 116 of the interconnect structure 110. In some embodiments, the conductive connectors 164 are referred to as controlled collapse chip connection (C4) bumps. In some other embodiments, the conductive connectors 164 are micro bumps, electroless nickel-electroless palladium-immersion gold technique (ENEPIG) formed bumps, ball grid array (BGA) bumps, or the like.

Afterwards, as shown in FIG. 1F, the structure as shown in FIG. 1E is flipped and the carrier substrate 160 is removed to expose the top surface of the substrate 122, in accordance with some embodiments of the disclosure.

Next, as shown in FIG. 1G, a number of the protruding structures 210 are formed on the substrate 122 of the semiconductor die 120, in accordance with some embodiments of the disclosure. The protruding structures 210 are formed on the substrate 122 and in direct contact with the substrate 122 of the semiconductor die 120. The protruding structures 210 are parallel with each other. The protruding structures 210 protrude from the top surface of the substrate 122 of the semiconductor die 120. In other words, the protruding structures 210 are extended upwardly from the top surface of the substrate 122 of the semiconductor die 120.

In some embodiments, the protruding structures 210 are made of thermal conductive materials. In some embodiments, the thermal conductive materials of the protruding structures 210 include aluminum (Al), Al alloy, copper (Cu), Cu alloy, silver (Ag), Ag alloy, gold (Au), Au alloy, a combination thereof, or another applicable material. In some embodiments, the thermal conductive materials of the protruding structures 210 have thermal conductivity in a range from about 200 W/m·K to about 2000 W/mK.

In some embodiments, the protruding structures 210 are formed by a deposition process, such as a chemical vapor deposition (CVD) process, or a physical vapor deposition (PVD) process, electroplating, electroless plating, and/or printing.

Afterwards, as shown in FIG. 1H, a lid structure 310 is provided, and a number of additional protruding structures 320 are formed below a lower surface of the lid structure 310, in accordance with some embodiments of the disclosure.

The lid structure 310 has a main portion 310a and leg portions 310b extending from the main portion 310a. The leg portions 310b are configured to attach to a package substrate 360 (see FIG. 1I). In some embodiments, the lid structure 310 has a high thermal conductivity, for example, between about 200 W/mK to about 400 W/mK. In some embodiments, the lid structure 310 is made of copper (Cu), copper alloy, copper tungsten (CuW), or aluminum-silicon-carbide (AlSiC) or applicable material.

The additional protruding structures 320 are formed below the lid structure 310 and in direct contact with the lower surface of the lid structure 310. The additional protruding structures 320 are parallel with each other. In some embodiments, the protruding structures 210 and the additional protruding structures 320 are made of different materials. In some other embodiments, the protruding structures 210 and the additional protruding structures 320 are made of the same materials.

In some embodiments, the additional protruding structures 320 are made of thermal conductive materials. In some embodiments, the thermal conductive materials of the additional protruding structures 320 include aluminum (Al), Al alloy, copper (Cu), Cu alloy, silver (Ag), Ag alloy, gold (Au), Au alloy, a combination thereof, or another applicable material. In some embodiments, the thermal conductive materials of the additional protruding structures 320 have thermal conductivity in a range from about 200 W/m·K to about 2000 W/mK. In some embodiments, the additional protruding structures 320 are formed by a deposition process, such as a chemical vapor deposition (CVD) process, or a physical vapor deposition (PVD) process, electroplating, electroless plating, and/or printing. In some other embodiments, the additional protruding structures 320 are formed by metal precision processing.

Afterwards, as shown in FIG. 1I, the semiconductor die 120 is bonded to a package substrate 360 through the conductive connectors 164, in accordance with some embodiments. In some embodiments, the package substrate 360 is a printed circuit board (PCB), a ceramic substrate or another suitable package substrate. During bonding of the semiconductor die 120 to the package substrate 360, the protruding structures 210 are laterally interleaved with the additional protruding structures 320.

Next, one or more thermal conductive materials 325 are dispersed on the semiconductor die 120 and between the protruding structures 210 and the additional protruding structures 320, and then cured by applying heat to form a thermal interface material (TIM) structure 350. The lid structure 310 is attached to the package substrate 360 by an adhesive 364.

The protruding structures 210 and the additional protruding structures 320 are encapsulated by the thermal conductive materials 325 to form the thermal interface material (TIM) structure 350 on the semiconductor die 120. The thermal interface material (TIM) structure 350 is configured to dissipate thermal energy or heat from the semiconductor die 120 to the lid structure 310.

In some embodiments, the thermal conductive materials 325 include aluminum oxide, boron nitride, aluminum nitride, aluminum, copper, silver, indium, a combination thereof, or applicable material.

In some embodiments, the thermal interface material (TIM) structure 350 includes a polymer material. In some embodiments, the thermal interface material (TIM) structure 350 includes other materials, such as a metallic-based or solder-based material comprising silver, indium paste, or applicable material. In some other embodiments, the thermal interface material (TIM) structure 350 includes a film-based or sheet-based material, such as a sheet-based material including synthesized carbon nanotubes (CNTs) or a thermally conductive sheet having vertically oriented graphite fillers. In some embodiments, the adhesive 364 is made of polymer having a good thermal conductivity.

Since the protruding structures 210 are physically and thermally connected to the substrate 122 of the semiconductor die 120, the heat can be transferred vertically by the protruding structures 210. The additional protruding structures 320 and the protruding structures 210 are alternatively arranged, and the heat can be transferred horizontally from the protruding structures 210 to the additional protruding structures 320 through the thermal conductive materials 325. Since the additional protruding structures 320 are physically and thermally connected to the lid structure 310, the heat can be transferred vertically again from the additional protruding structures 320 to the lid structure 310. The arrows 327 represent a general direction that the heat is dissipated from the semiconductor die 120, through the protruding structures 210 and the additional protruding structures 320 to the lid structure 310, in some embodiments.

The heat generated by the semiconductor die 120 can be transferred to the external environment by the thermal interface material (TIM) structure 350. The heat can be transferred vertically and horizontally through the protruding structures 210 and additional protruding structures 320. The protruding structures 210 and additional protruding structures 320 are stacked in an alternating manner to improve the heat dissipation efficiency.

In addition, the protruding structures 210 are thermally connected to the semiconductor die 120, and the additional protruding structures 320 are thermally connected to the lid structure 310. The contact area of the protruding structures 210 and the semiconductor die 120 and the contact area of the additional protruding structures 320 and the lid structure 310 are large when compared with the thermal interface material (TIM) structure 350 without any protruding structures to increase heat dissipation efficiency.

The thermal interface material (TIM) structure 350 with protruding structures 210 and additional protruding structures 320 provides high heat dissipation efficiency, and therefore, the performance of the of the package structure 100a is improved.

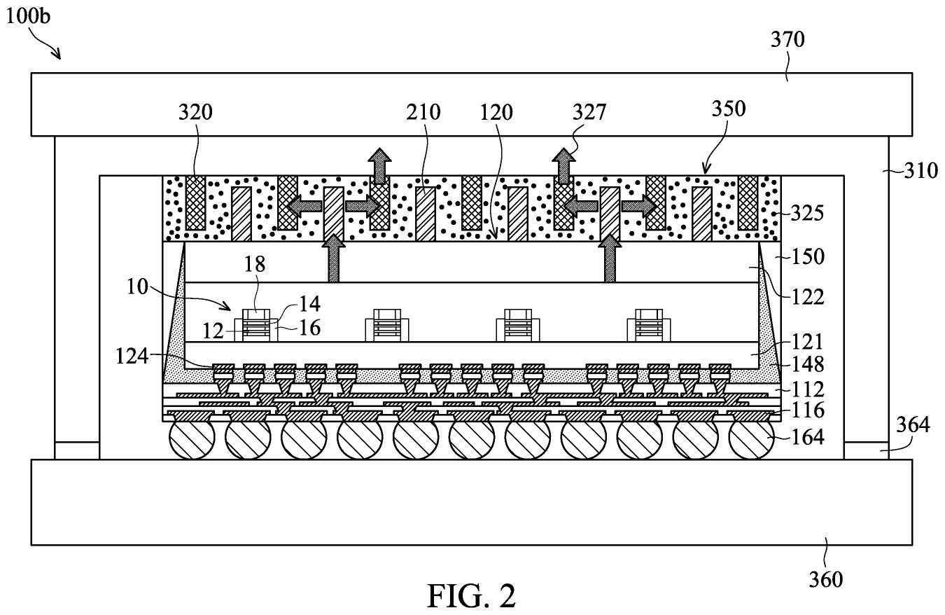

FIG. 2 shows a cross-sectional representation of a package structure 100b (e.g., a semiconductor device structure), in accordance with some embodiments of the disclosure. The package structure 100b is similar to, or the same as, the package structure 100a shown in FIGS. 1A-1I. Processes and materials used to form the package structure 100b may be similar to, or the same as, those used to form the package structure 100a and a detailed description thereof is not repeated herein.

The difference between FIG. 2 and FIG. 1I is that an external cooling unit 370 is formed on the lid structure 310. The external cooling unit 370 is physically and thermally connected to the lid structure 310. The external cooling unit 370 is configured to dissipate the heat from the semiconductor die 120 to the external environment by the thermal interface material (TIM) structure 350 and the lid structure 310.

In some embodiments, the external cooling unit 370 includes fins for radiative heat dissipation to the surrounding environment. In some embodiments, the external cooling unit 370 includes at least one thermal conductive plate. In some other embodiments, the external cooling unit 370 includes another suitable heat transferring structure to help reduce heat generated by the semiconductor die 120.

In some embodiments, the area of external cooling unit 370 is greater than the area of the lid structure and the area of the semiconductor die 120. The external cooling unit 370 is added after the lid structure 310 is formed on the package substrate 360. In some other embodiments, the external cooling unit 370 is added on the lid structure 310 before the lid structure 310 is formed on the package substrate 360.

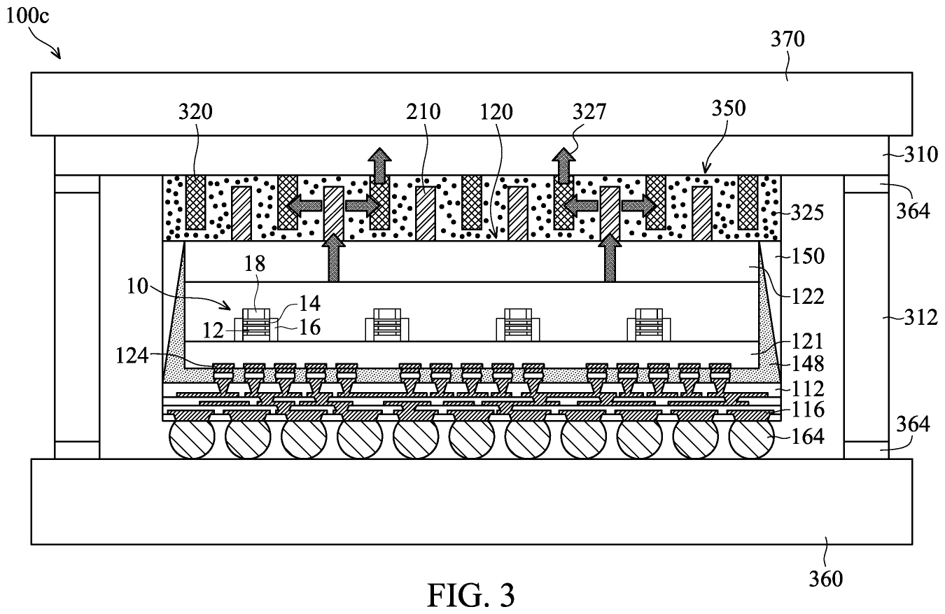

FIG. 3 shows a cross-sectional representation of a package structure 100c, in accordance with some embodiments of the disclosure. The package structure 100c is similar to, or the same as, the package structure 100a shown in FIGS. 1A-1I. Processes and materials used to form package structure 100c may be similar to, or the same as, those used to form the package structure 100a and a detailed description thereof is not repeated herein.

The difference between FIG. 3 and FIG. 1I is that the leg portions 310b of the lid structure 310 are replaced with a ring structure 312. The material of the ring structure 312 is different from the material of the lid structure 310. The ring structure 312 is bonded to the lid structure 310 by the adhesive 364.

The ring structure 312 is made of the low coefficient of thermal expansion material. In some embodiments, the ring structure 312 is made of copper, copper alloy, copper tungsten (CuW), or aluminum-silicon-carbide (AlSiC), or another applicable material.

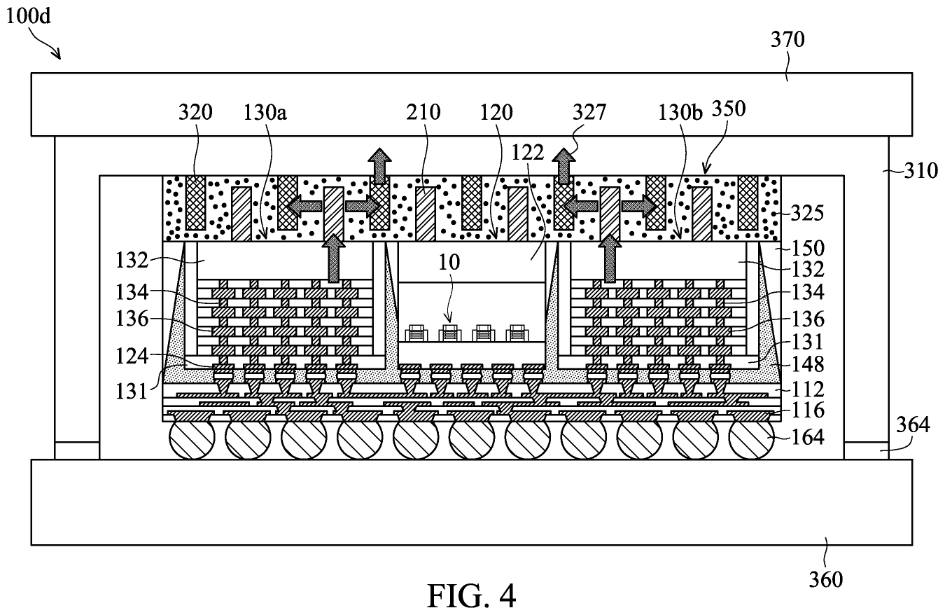

FIG. 4 shows a cross-sectional representation of a package structure 100d, in accordance with some embodiments of the disclosure. The package structure 100d is similar to, or the same as, the package structure 100a shown in FIGS. 1A-1I. Processes and materials used to form package structure 100d may be similar to, or the same as, those used to form the package structure 100a and a detailed description thereof is not repeated herein.

The difference between FIG. 4 and FIG. 1I is that a first stacked die 130a and a second stacked die 130b are formed adjacent to the semiconductor die 120, and the external cooling unit 370 is formed on the lid structure 310. The protruding structures 210 are also formed on and physically and thermally connected to the first stacked die 130a and the second stacked die 130b. More specifically, the protruding structures 210 are formed on the top substrates 132 of the first stacked die 130a and the second stacked die 130b.

The semiconductor die 120 is between the first stacked die 130a and the second stacked die 130b. The first stacked die 130a and the second stacked die 130b are disposed over the interconnect structure 110. The first stacked die 130a and the second stacked die 130b are at opposite sides of the semiconductor die 120. Each of the first stacked die 130a and the second stacked die 130b may include a number of semiconductor dies. In some embodiments, the semiconductor dies are memory dies. The semiconductor die 120 has a different function from each of the memory dies. The memory dies may include static random access memory (SRAM) devices, dynamic random access memory (DRAM) devices, high bandwidth memory (HBM) or another memory dies. The number of the semiconductor dies is not limited to four, and the number can be adjusted according to the actual application.

The semiconductor dies are stacked on a buffer die (or base die) 131 that performs as a logic circuit. The semiconductor dies are bonded to each other by a number of bonding structures 136. A number of through substrate vias (TSVs) 134 are formed in the semiconductor dies. The signal between the semiconductor may be transferred through the through substrate vias (TSVs) 134 and the bonding structures 136. A top substrate 132 is formed on the semiconductor dies. In some embodiments, the top substrate 132 includes silicon, elementary semiconductor materials, compound semiconductor materials, and/or alloy semiconductor materials.

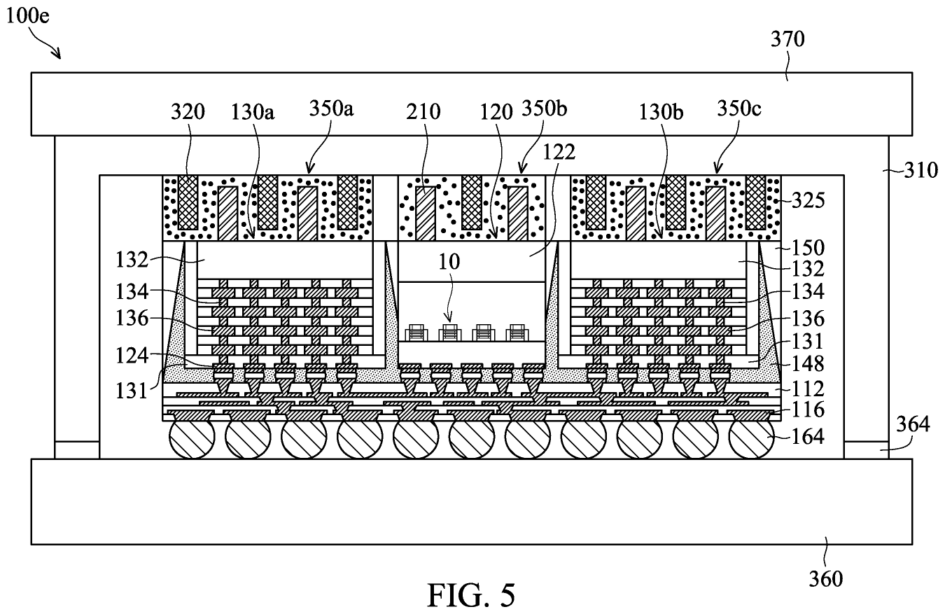

FIG. 5 shows a cross-sectional representation of a package structure 100e, in accordance with some embodiments of the disclosure. The package structure 100e is similar to, or the same as, the package structure 100d shown in FIG. 4. Processes and materials used to form package structure 100e may be similar to, or the same as, those used to form the package structure 100d and a detailed description thereof is not repeated herein.

The difference between FIG. 5 and FIG. 4 is that the thermal interface material (TIM) structure 350 includes a first portion 350a, a second portion 350b, and a third portion 350c. The first portions 350a, the second portion 350b, and the third portion 350c of thermal interface material (TIM) structure 350 are separated from each other. The first portions 350a, the second portion 350b, and the third portion 350c of thermal interface material (TIM) structure 350 are physically disconnected.

The first portion 350a of the thermal interface material (TIM) structure 350 is separated from the second portion 350b by the air, and the second portion 350b is separated from the third portion 350c by the air. The air gap between adjacent dies can reduce lateral thermal interaction between the dies.

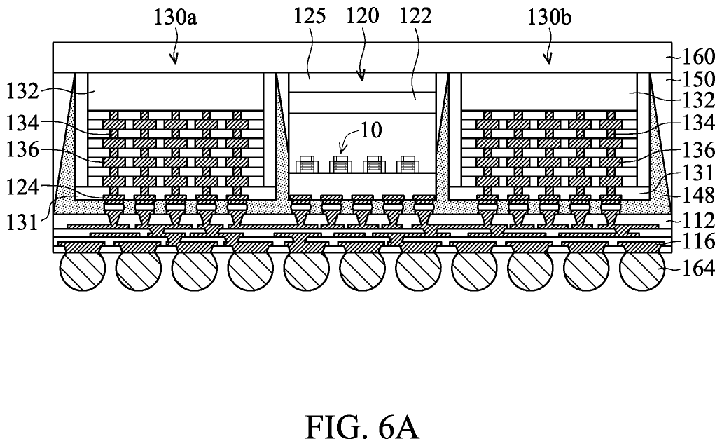

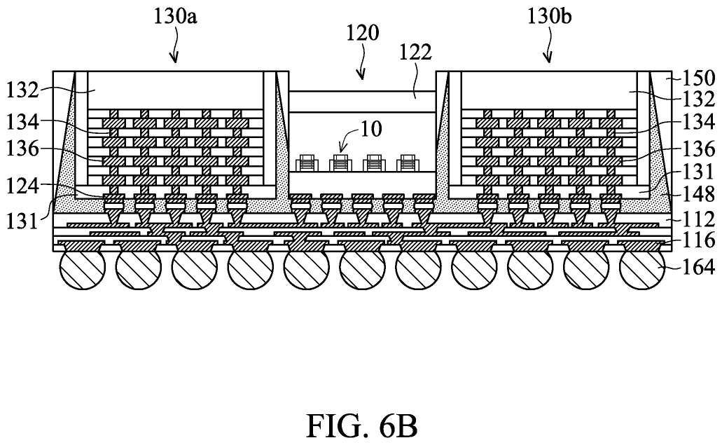

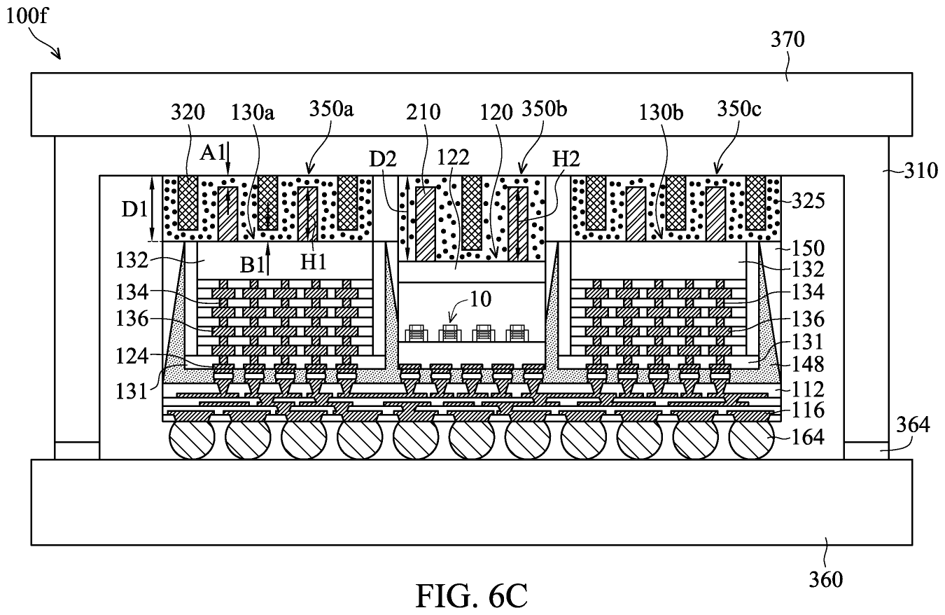

FIGS. 6A-6C shows a cross-sectional representation of a package structure 100f, in accordance with some embodiments of the disclosure. The package structure 100f is similar to, or the same as, the package structure 100e shown in FIG. 5. Processes and materials used to form package structure 100f may be similar to, or the same as, those used to form the package structure 100e and a detailed description thereof is not repeated herein.

The difference between FIG. 6A and FIG. 5 is that a removable film 125 is formed over the substrate 122 of the semiconductor die 120, in accordance with some embodiments of the disclosure. The top surface of the removable film 125 may be formed to be higher than the top surface of the first stacked die 130a and the top surface of the second stacked die 130b. The removable film 125 is used as a release film and will be removed in the following process. Afterwards, the package layer 150 is formed over the underfill layer 148 and the removable film 125. Next, a portion of the removable film 125 and a portion of the package layer 150 are removed to expose the top surface of the top substrate 132 by a planarization process, such as a chemical mechanical polishing (CMP) process. After the planarization process, the top surface of the removable film 125 may be a same height as the top surfaces of the first stacked die 130a and the second stacked die 130b. The carrier substrate 160 is formed over the removable film 125 and the top substrate 132, and the conductive connectors 164 are formed below the conductive layer 116 of the interconnect structure 110.

In some embodiments, the removable film 125 is made of grindable and low out-gassing materials. In some embodiments, the removable film 125 is made of thermoplastic material, such as polyethylene (PE), polypropylene (PP), polyethyleneterephthalate (PET) or another applicable material.

Next, as shown in FIG. 6B, the carrier substrate 160 is removed, and then the removable film 125 is removed, in accordance with some embodiments of the disclosure. As a result, the top surface of the semiconductor die 120 is lower than the top surface of the first stacked die 130a and the top surface of the second stacked die 130b. In other words, the top surface of the first stacked die 130a and the top surface of the second stacked die 130b are higher than the top surface of the semiconductor die 120. In some embodiments, the removable film 125 is removed by an etching process. For example, the removable film 125 is removed by a wet etching process, such as an acid solution.

Next, as shown in FIG. 6C, the first portions 350a of the thermal interface material (TIM) structure 350 is formed on the first stacked die 130a, the second portion 350b of the thermal interface material (TIM) structure 350 is formed on the semiconductor die 120, and the third portion 350c of the thermal interface material (TIM) structure 350 is formed on the second stacked die 130b.

As shown in FIG. 6C, each of the protruding structures 210 directly above the first stacked die 130a has a first height H1 along the vertical direction. Each of the protruding structures 210 directly above the semiconductor die 120 has a second height H2 along the vertical direction. In some embodiments, the second height H2 is greater than the first height H1.

The first portion 350a of the thermal interface material (TIM) structure 350 has a first thickness D1 along the vertical direction, and the second portion 350b of the thermal interface material (TIM) structure 350 has a second thickness D2 along the vertical direction. In some embodiments, the second thickness D2 is greater than the first thickness D1. In some embodiments, the second thickness D2 is in a range from about 20 micrometer (μm) to about 300 micrometer (μm).

There is a distance A1 between the top surface of the protruding structures 210 and the bottom surface of the lid structure. In some embodiments, the distance A1 is in a range from about 5 micrometer (μm) to about 30 micrometer (μm). There is distance B1 between the bottom surface of the additional protruding structures 320 and the top surface of the top substrate 132. In some embodiments, the distance B1 is in a range from about 5 micrometer (μm) to about 30 micrometer (μm).

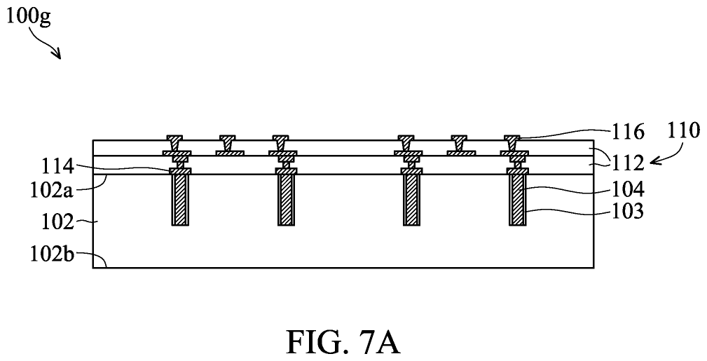

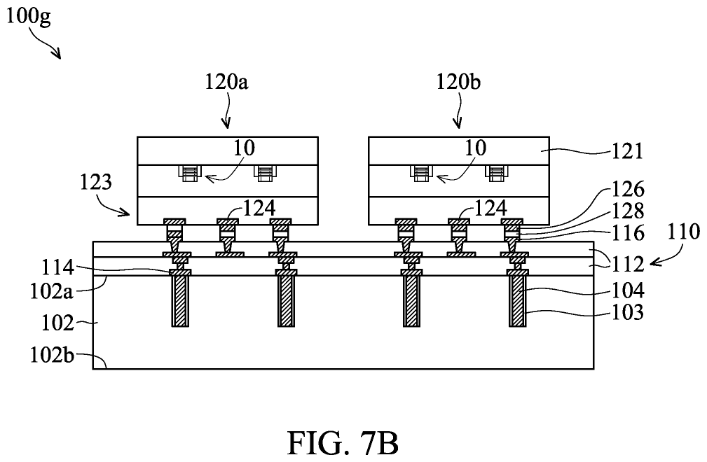

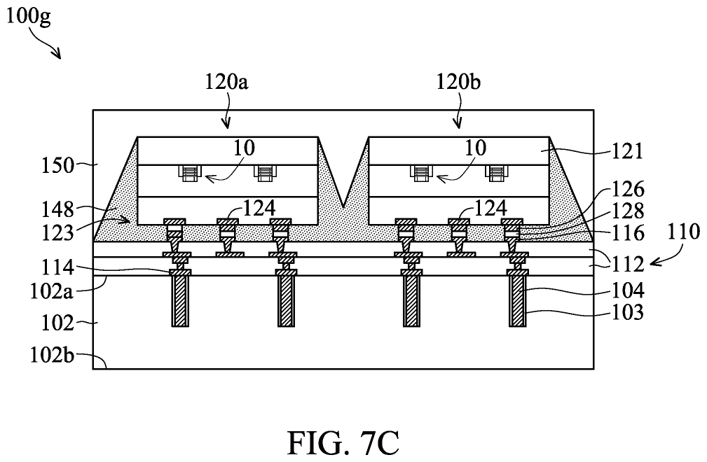

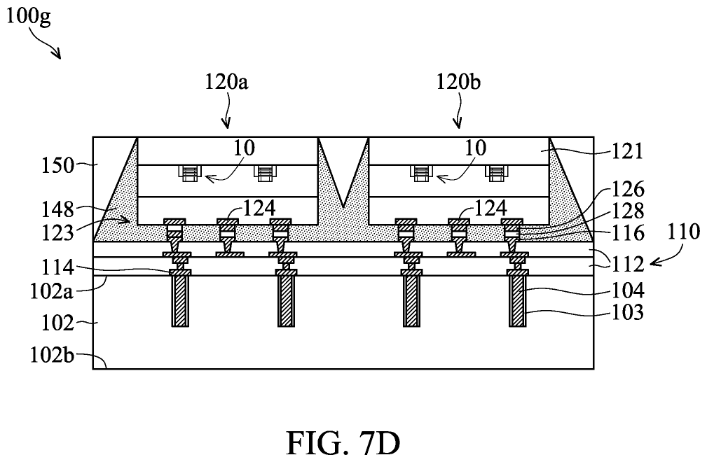

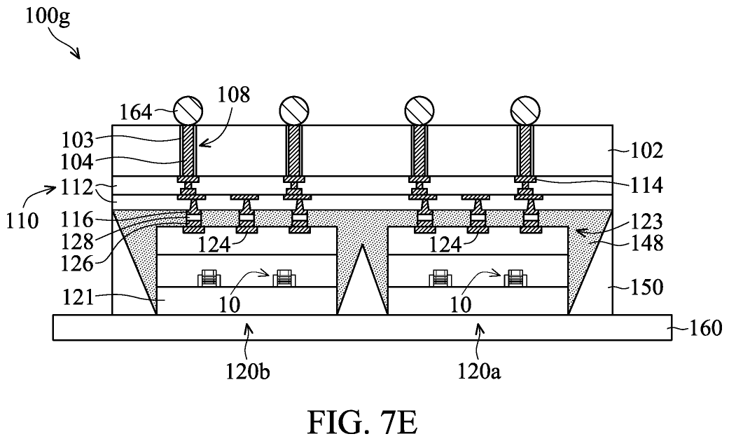

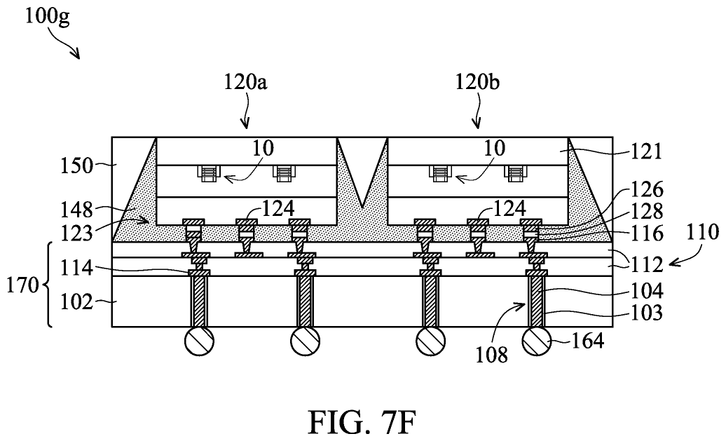

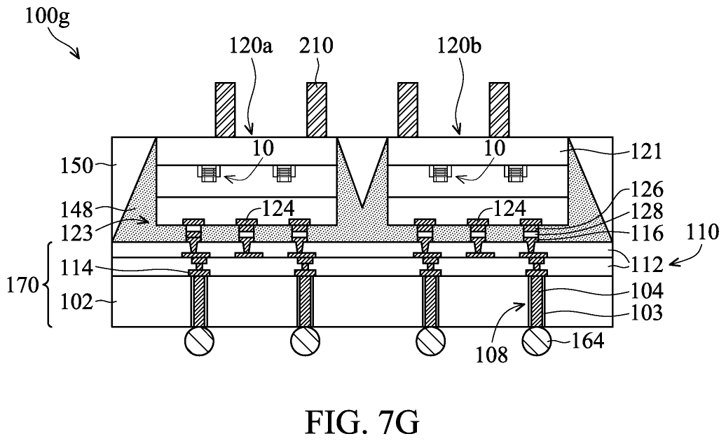

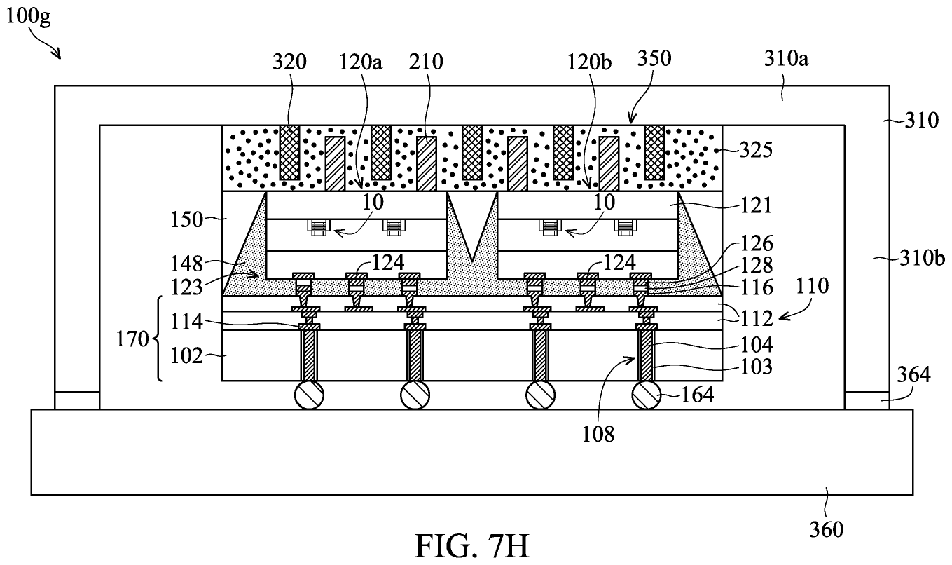

FIGS. 7A-7H show cross-sectional representations of various stages of forming a package structure 100g, in accordance with some embodiments of the disclosure. Processes and materials used to form package structure 100g may be similar to, or the same as, those used to form the package structure 100a and a detailed description thereof is not repeated herein.

As show in FIG. 7A, the conductive structures 104 are formed in the substrate 102. The conductive structures 104 extend from the front surface 102a of the substrate 102 towards the back surface 102b of the substrate 102. In some embodiments, the conductive structures 104 are formed by forming a number of trenches (not shown) which extend from the front surface 102a of the substrate 102. Afterwards, a barrier layer 103 is filled into each of the trenches, and the conductive structure 104 is formed on the barrier layer 103 and in each of the trenches.

The interconnect structure 110 is formed over the conductive structures 104 and the substrate 102. The interconnect structure 110 may be used as a redistribution (RDL) structure for routing. The interconnect structure 110 includes multiple conductive layers 114 and conductive layers 116 formed in multiple dielectric layers 112. In some embodiments, the conductive layers 116 are exposed at or protrude from the top surface of the top of the dielectric layers 112 to serve as bonding pads.

The conductive layers 114 and the conductive layers 116 may be made of copper (Cu), copper alloy, aluminum (Al), aluminum alloy, tungsten (W), tungsten alloy, titanium (Ti), titanium alloy, tantalum (Ta) or tantalum alloy. In some embodiments, the conductive layers 114 and the conductive layers 116 are formed by an electroplating, electroless plating, printing, a chemical vapor deposition (CVD) process, or a physical vapor deposition (PVD) process.

Afterwards, as shown in FIG. 7B, a first semiconductor die 120a and a second semiconductor die 120b are formed over the conductive layer 116, in accordance with some embodiments of the disclosure. Each of the first semiconductor die 120a and the second semiconductor die 120b includes a substrate 121 and an interconnect structure 123 over the substrate 121. The interconnect structure 123 of the semiconductor die 120 includes a number of conductive pads 124.

In some embodiments, the first semiconductor die 120a and the second semiconductor die 120b are sawed from a wafer, and may be a “known-good-die”. The first semiconductor die 120a and the second semiconductor die 120b may be a system-on-chip (SoC) chip or memory die. In some other embodiments, first semiconductor die 120a and the second semiconductor die 120b are a system on integrated circuit (SoIC) device that includes two or more chips with integrated functions.

In some embodiments, a number of conductive layers 126 are formed below the conductive pads 124 of the first semiconductor die 120a and the second semiconductor die 120b, and each of the conductive layers 126 is bonded to each of the conductive layers 116 through a number of conductive connectors 128.

The conductive layers 126 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive layers 126 are formed by an electroplating, electroless plating, printing, a chemical vapor deposition (CVD) process, or a physical vapor deposition (PVD) process.

The conductive connector 128 is made of solder materials, such as tin (Sn), tin-silver (SnAg), tin-lead (SnPb), tin-copper (SnCu), tin-silver-copper (SnAgCu), tin-silver-zinc (SnAgZn), tin-zinc (SnZn), tin-bismuth-indium (SnBiIn), tin-indium (SnIn), tin-gold (SnAu), tin-zinc-indium (SnZnIn), tin-silver-Antimony (SnAgSb) or another applicable material. In some embodiments, the conductive connectors 128 are formed by electroplating, electroless plating, printing, a chemical vapor deposition (CVD) process, or a physical vapor deposition (PVD) process.

Afterwards, as shown in FIG. 7C, the underfill layer 148 is formed between the first semiconductor die 120a, the second semiconductor die 120b and the interconnect structure 110, in accordance with some embodiments of the disclosure. The underfill layer 148 surrounds and protects the conductive layers 126 and the conductive connectors 128. In some embodiments, the underfill layer 148 is in direct contact with the conductive layers 126 and the conductive connectors 128.

Afterwards, the package layer 150 is formed over the underfill layer 148 and the substrate 121 of the semiconductor die 120. The package layer 150 is also formed over the substrate 122.

The package layer 150 surrounds and protects the first semiconductor die 120a and the second semiconductor die 120b. In some embodiments, the package layer 150 is in direct contact with a portion of the first semiconductor die 120a and the second semiconductor die 120b.

Next, as shown in FIG. 7D, a portion of the package layer 150 is removed to expose the top surface of the substrate 121, in accordance with some embodiments of the disclosure. In some embodiments, the portion of the package layer 150 is removed by a planarization process, such as a chemical mechanical polishing (CMP) process.

Afterwards, as shown in FIG. 7E, the carrier substrate 160 is formed over the substrate 121 and the package layer 150, and the structure as shown in FIG. 7D is flipped, in accordance with some embodiments of the disclosure. Next, the substrate 102 is thinned from the back surface 102b until the conductive structures 104 are exposed. In some embodiments, the conductive structures 104 and the barrier layer 103 become exposed and penetrate through the thinned substrate 102. As a result, the through via structures 108 are formed in the substrate 102. In some embodiments, the conductive structures 104 are through substrate via (TSV) structures.

Afterwards, a number of the conductive connectors 164 are formed over the through via structures 108. In some embodiments, the conductive connectors 164 are referred to as controlled collapse chip connection (C4) bumps. In some other embodiments, the conductive connectors 164 is micro bumps, electroless nickel-electroless palladium-immersion gold technique (ENEPIG) formed bumps, ball grid array (BGA) bumps, or the like.

Next, as shown in FIG. 7F, the structure as shown in FIG. 7E is flipped and the carrier substrate 160 is removed to expose the top surface of the substrate 121, in accordance with some embodiments of the disclosure. As a result, an interposer 170 is obtained. The interposer 170 includes the through via structures 108 in the substrate 102 and the interconnect structure 110 electrically connected to the through via structures 108. The first semiconductor dies 120a and the second semiconductor die 120b are electrically connected to the conductive connectors 164 by the interposer 170.

Afterwards, as shown in FIG. 7G, a number of the protruding structures 210 are formed on the substrate 121 of the first semiconductor die 120a and the second semiconductor die 120b, in accordance with some embodiments of the disclosure. The protruding structures 210 are formed on the substrate 121 and in direct contact with the substrates 121 of the first semiconductor die 120a and the second semiconductor die 120b. The protruding structures 210 are parallel with each other. The protruding structures 210 protrude from the top surface of the top surfaces of the substrates 121 of the first semiconductor die 120a and the second semiconductor die 120b. In other words, the protruding structures 210 are extended upwardly from the first semiconductor die 120a and the second semiconductor die 120b.

Next, as shown in FIG. 7H, the lid structure 310 is provided, and a number of additional protruding structures 320 are formed below the lower surface of the lid structure 310, in accordance with some embodiments of the disclosure. Next, the protruding structures 210, and the additional protruding structures 320 are encapsulated by the thermal conductive materials 325 to form the thermal interface material (TIM) structure 350, in accordance with some embodiments of the disclosure. The thermal interface material (TIM) structure 350 is configured to dissipate thermal energy or heat from the first semiconductor die 120a and the second semiconductor die 120b to the lid structure 310. Next, the lid structure 310 is attached to the package substrate 360 by the adhesive 364.

The additional protruding structures 320 are formed below the lid structure 310 and in direct contact with the lower surface of the lid structure 310. The additional protruding structures 320 are extended downwardly from the lid structure 310.

In some embodiments, the protruding structures 210 and the additional protruding structures 320 are made of different materials. In some other embodiments, the protruding structures 210 and the additional protruding structures 320 are made of the same materials.

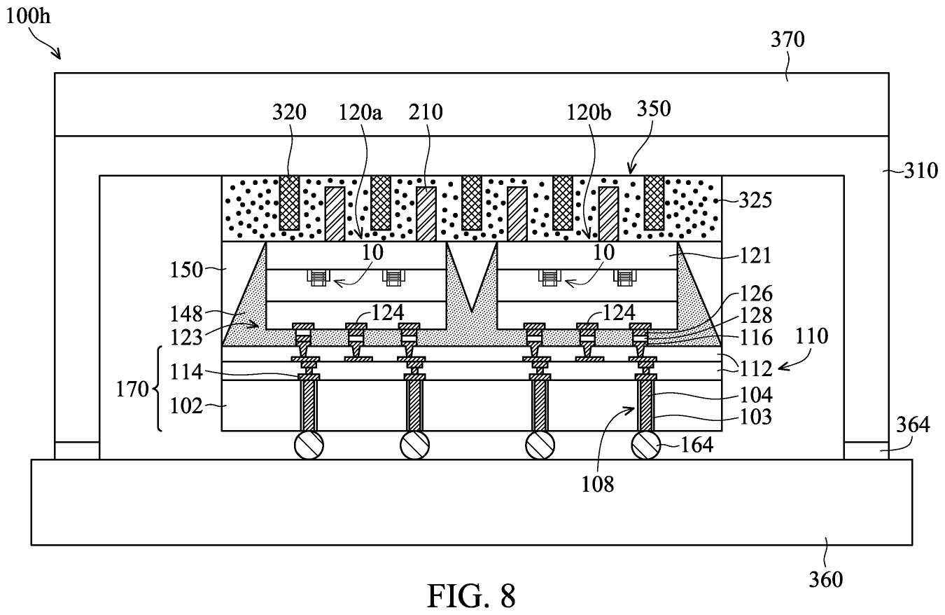

FIG. 8 shows a cross-sectional representation of a package structure 100h, in accordance with some embodiments of the disclosure. The package structure 100h is similar to, or the same as, the package structure 100g shown in FIGS. 7A-7H. Processes and materials used to form package structure 100h may be similar to, or the same as, those used to form the package structure 100g and a detailed description thereof is not repeated herein.

The difference between FIG. 8 and FIG. 7H is that the external cooling unit 370 is formed on the lid structure 310. The external cooling unit 370 is thermally connected to the lid structure 310. The external cooling unit 370 is configured to dissipate the heat from the first semiconductor die 120a and the second semiconductor die 120b to the external environment by the thermal interface material (TIM) structure 350 and the lid structure 310.

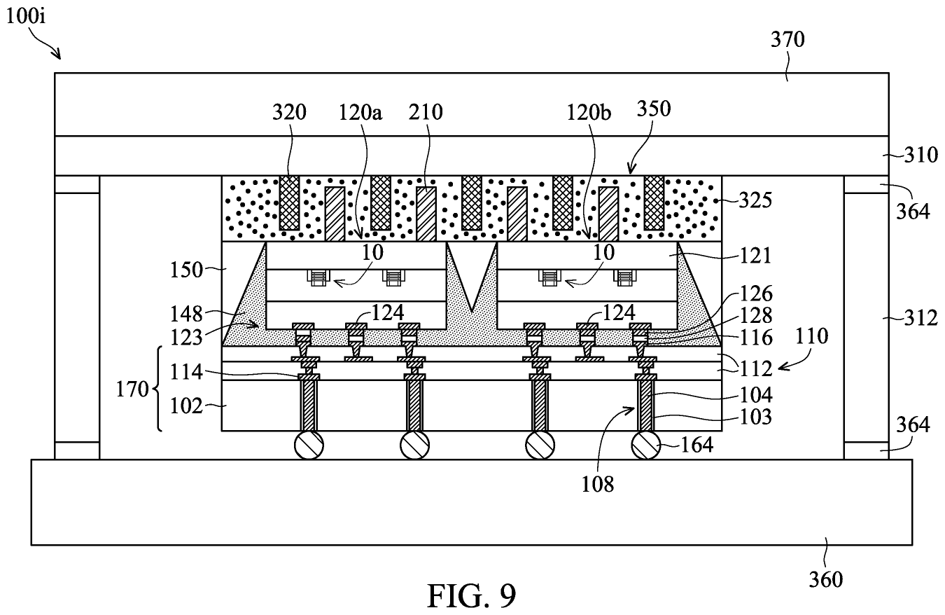

FIG. 9 shows a cross-sectional representation of a package structure 100i, in accordance with some embodiments of the disclosure. The package structure 100i is similar to, or the same as, the package structure 100h shown in FIG. 8. Processes and materials used to form package structure 100i may be similar to, or the same as, those used to form the package structure 100h and a detailed description thereof is not repeated herein.

The difference between FIG. 9 and FIG. 8 is that the leg portions 310b of the lid structure 310 are replaced with the ring structure 312. The material of the ring structure 312 is different from the material of the lid structure 310. The ring structure 312 is bonded to the lid structure 310 by the adhesive 364.

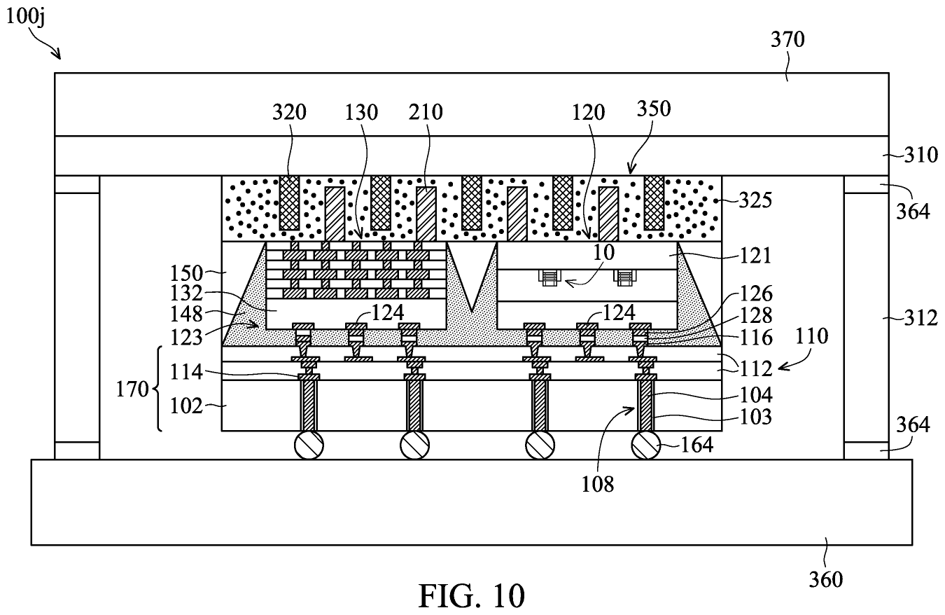

FIG. 10 shows a cross-sectional representation of a package structure 100j, in accordance with some embodiments of the disclosure. The package structure 100j is similar to, or the same as, the package structure 100i shown in FIG. 9. Processes and materials used to form package structure 100j may be similar to, or the same as, those used to form the package structure 100i and a detailed description thereof is not repeated herein.

The difference between FIG. 10 and FIG. 9 is that the stacked die 130 is formed adjacent to the semiconductor die 120. The protruding structures 210 are also formed on and connected to the stacked die 130. More specifically, the protruding structures 210 are formed on the top surface of the stacked die 130.

The stacked die 130 is disposed over the interconnect structure 110. Each of the stacked die 130 may include a number of semiconductor dies. In some embodiments, the semiconductor dies are memory dies. The semiconductor die 120 has a different function from each of the memory dies. The memory dies may include static random access memory (SRAM) devices, dynamic random access memory (DRAM) devices, high bandwidth memory (HBM) or another memory dies. The number of the semiconductor dies are not limited to four, and the number can be adjusted according to the actual application.

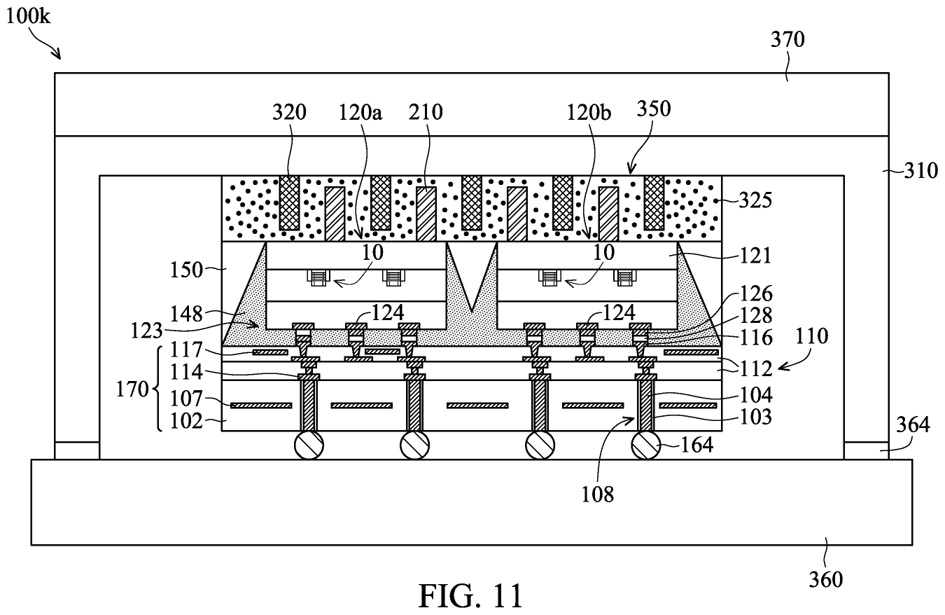

FIG. 11 shows a cross-sectional representation of a package structure 100k, in accordance with some embodiments of the disclosure. The package structure 100k is similar to, or the same as, the package structure 100h shown in FIG. 8. Processes and materials used to form package structure 100k may be similar to, or the same as, those used to form the package structure 100h and a detailed description thereof is not repeated herein.

The difference between FIG. 11 and FIG. 8 is that a number of optical components 107 are formed in the substrate 102, and a number of optical components 117 are formed in the dielectric layer 112 of the interconnect structure 110 of the interposer 170. The optical components 107 and 117 are configured to transfer the optical signal.

The optical components 107 and 117 include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like.

The optical components 107 and 117 are formed by a patterning process. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process may include a dry etching process or a wet etching process.

It should be noted that since the distance between the optical components 117 of the interconnect structure 110 and the optical components 107 of the substrate 102 is greatly reduced, the coupling efficiency is greatly improved.

FIG. 12 shows a cross-sectional representation of a package structure 100l, in accordance with some embodiments of the disclosure. The package structure 100l is similar to, or the same as, the package structure 100j shown in FIG. 10. Processes and materials used to form package structure 100l may be similar to, or the same as, those used to form the package structure 100j and a detailed description thereof is not repeated herein.

The difference between FIG. 12 and FIG. 10 is that the first portions 350a of the thermal interface material (TIM) structure 350 is formed on the stacked die 130, and the second portion 350b of the thermal interface material (TIM) structure 350 is formed on the semiconductor die 120.

As shown in FIG. 12, each of the protruding structures 210 directly above the stacked die 130 has a first height H1 along the vertical direction. Each of the protruding structures 210 directly above the semiconductor die 120 has a second height H2 along the vertical direction. In some embodiments, the second height H2 is greater than the first height H1.

The first portion 350a of the thermal interface material (TIM) structure 350 has a first thickness D1 along the vertical direction, and the second portion 350b of the thermal interface material (TIM) structure 350 has a second thickness D2 along the vertical direction. In some embodiments, the second thickness D2 is greater than the first thickness D1.

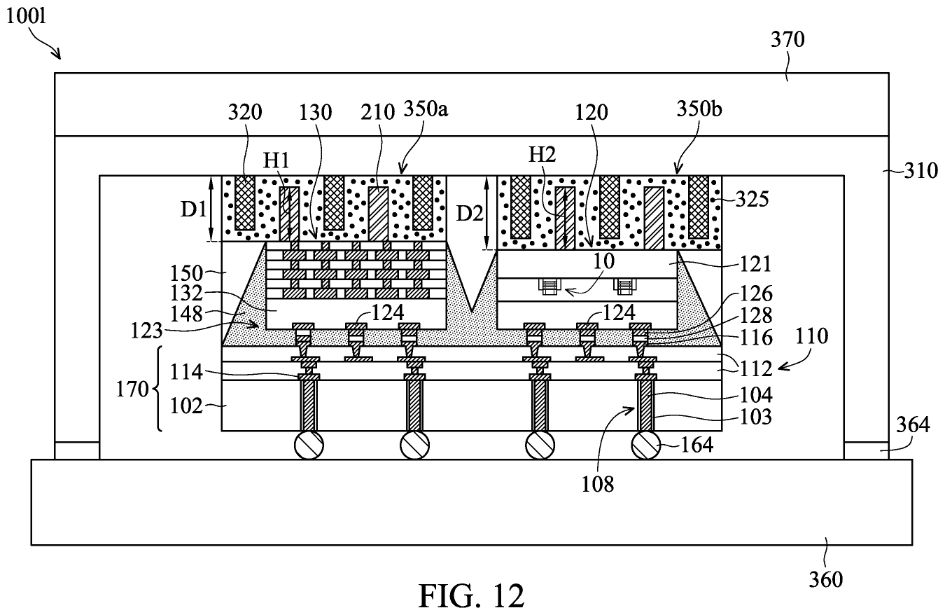

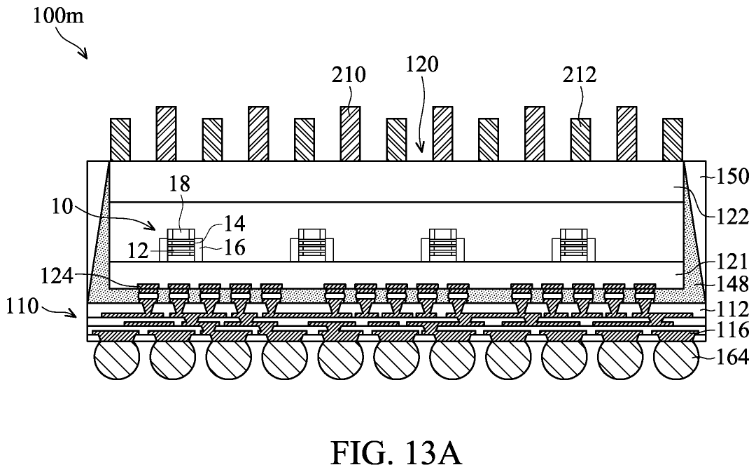

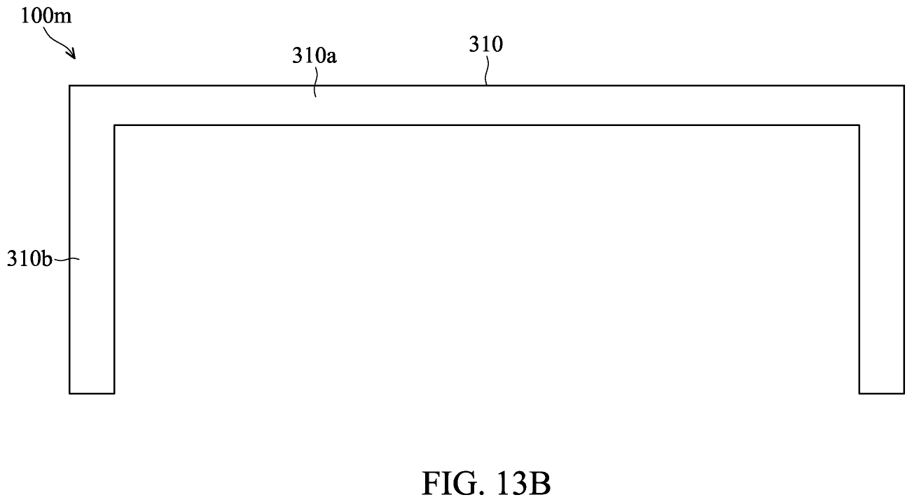

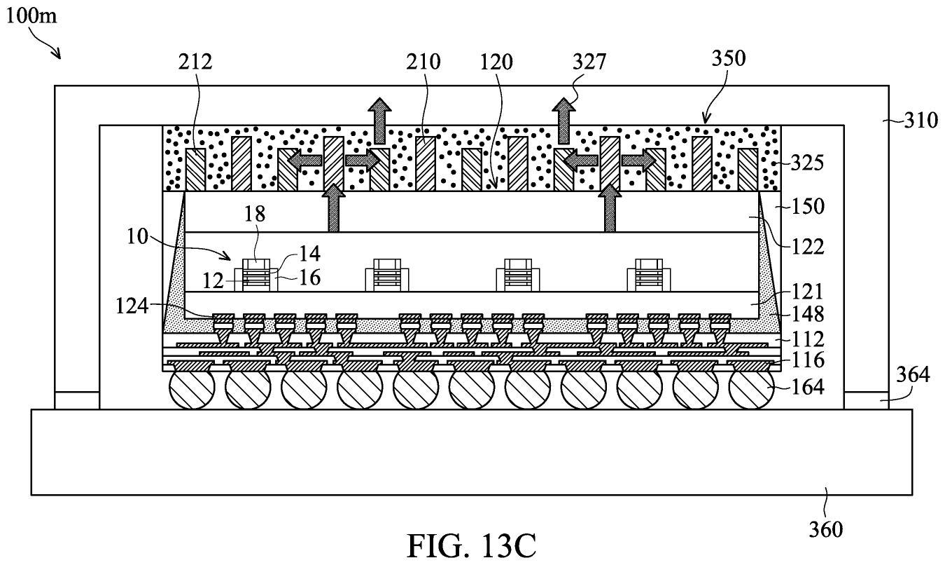

FIG. 13A-13C show cross-sectional representations of various stages of forming a package structure 100m, in accordance with some embodiments of the disclosure. The package structure 100m is similar to, or the same as, the package structure 100a shown in FIGS. 1A-1I. Processes and materials used to form package structure 100m may be similar to, or the same as, those used to form the package structure 100a and a detailed description thereof is not repeated herein.

The difference between FIG. 13A and FIG. 1G is that a number of the protruding structures 210 and a number of second protruding structures 212 are formed on the substrate 122 of the semiconductor die 120, in accordance with some embodiments of the disclosure. The protruding structures 210 and the second protruding structures 212 are formed on the substrate 122 and in direct contact with the substrate 122 of the semiconductor die 120. The protruding structures 210 and the second protruding structures 212 are parallel with each other. The protruding structures 210 and the second protruding structures 212 protrude from the top surface of the substrate 122 of the semiconductor die 120. In other words, the protruding structures 210 and the second protruding structures 212 are extended upwardly from the top surface of the substrate 122 of the semiconductor die 120. In some embodiments, the height of each of the protruding structures 210 is greater than the height of the each of the second protruding structures 212. In other words, the top surface of each of the protruding structures 210 is higher than the top surface of each of the second protruding structures 212. In some embodiments, the width of each of the protruding structures 210 is different from the width of each of the second protruding structures 212.

In some embodiments, the protruding structures 210 and the second protruding structures 212 are made of thermal conductive materials. In some embodiments, the thermal conductive materials of the protruding structures 210 and the second protruding structures 212 include aluminum (Al), Al alloy, copper (Cu), Cu alloy, silver (Ag), Ag alloy, gold (Au), Au alloy, a combination thereof, or another applicable material. In some embodiments, the thermal conductive materials of the protruding structures 210 and the second protruding structures 212 have thermal conductivity in a range from about 200 W/m· K to about 2000 W/mK.

In some embodiments, the protruding structures 210 and the second protruding structures 212 are formed by a deposition process, such as a chemical vapor deposition (CVD) process, or a physical vapor deposition (PVD) process.

Next, as shown in FIG. 13B, the lid structure 310 without any protruding structures is provided, in accordance with some embodiments of the disclosure.

Afterwards, as shown in FIG. 13C, the semiconductor die 120 is bonded to a package substrate 360 through the conductive connectors 164, in accordance with some embodiments. In some embodiments, the package substrate 360 is a printed circuit board (PCB), a ceramic substrate or another suitable package substrate.

Next, thermal conductive materials 325 are dispersed on the semiconductor die 120 and between the protruding structures 210 and the second protruding structures 212, and then cured by applying heat to form a thermal interface material (TIM) structure 350. The lid structure 310 is attached to the package substrate 360 by an adhesive 364.

The protruding structures 210 and the second protruding structures 212 are encapsulated by the thermal conductive materials 325 to form the thermal interface material (TIM) structure 350 on the semiconductor die 120. The thermal interface material (TIM) structure 350 is configured to dissipate thermal energy or heat from the semiconductor die 120 to the lid structure 310.

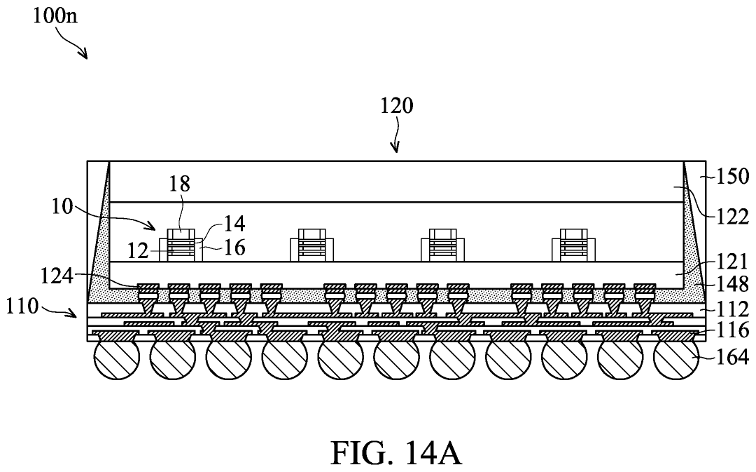

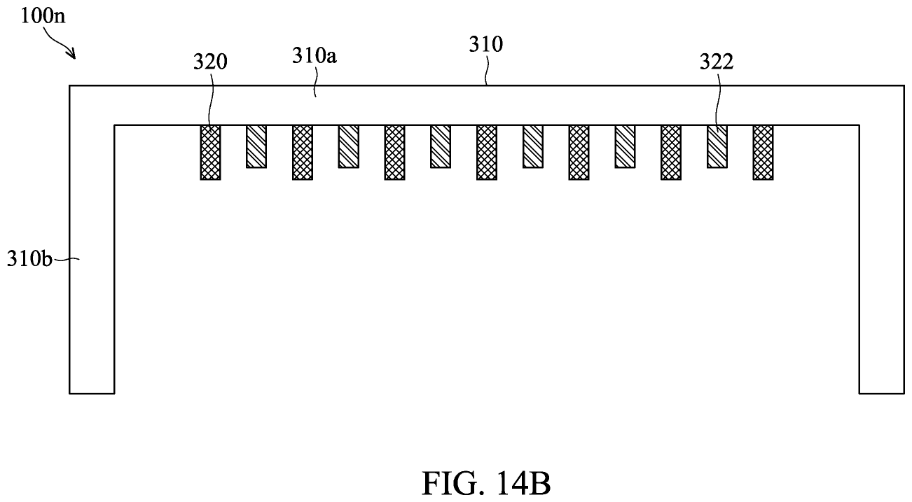

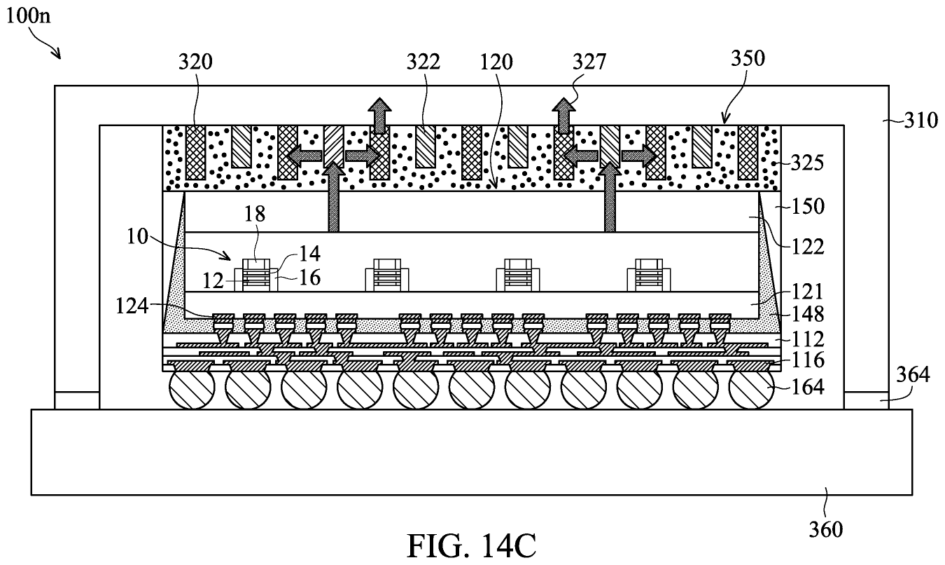

FIG. 14A-14C show cross-sectional representations of various stages of forming a package structure 100n, in accordance with some embodiments of the disclosure. The package structure 100n is similar to, or the same as, the package structure 100a shown in FIGS. 1A-1I. Processes and materials used to form package structure 100n may be similar to, or the same as, those used to form the package structure 100a and a detailed description thereof is not repeated herein.

The difference between FIG. 14A and FIG. 1G is that there is no protruding structures are formed on the substrate 122 of the semiconductor die 120, in accordance with some embodiments of the disclosure.

Next, as shown in FIG. 14B, the lid structure 310 is provided, and a number of the additional protruding structures 320 and a number of the second additional protruding structures 322 are formed below the lower surface of the lid structure 310, in accordance with some embodiments of the disclosure.

The lid structure 310 has a main portion 310a and leg portions 310b extending from the main portion 310a. The leg portions 310b are configured to attach to a package substrate 360 (see FIG. 1I). In some embodiments, the lid structure 310 has a high thermal conductivity, for example, between about 200 W/mK to about 400 W/mK. In some embodiments, the lid structure 310 is made of copper (Cu), copper alloy, copper tungsten (CuW), or aluminum-silicon-carbide (AlSiC) or applicable material.

The additional protruding structures 320 and the second additional protruding structures 322 are formed below the lid structure 310 and in direct contact with the bottom surface of the lid structure 310. The additional protruding structures 320 and the second additional protruding structures 322 are parallel with each other. In some embodiments, the height of each of the additional protruding structures 320 is greater than the height of each of the second additional protruding structures 322. In some embodiments, the width of each of the additional protruding structures 320 is different from the width of each of the second additional protruding structures 322.

In some embodiments, the protruding structures 210, the additional protruding structures 320, and the second additional protruding structures 322 are made of different materials. In some other embodiments, the protruding structures 210, the additional protruding structures 320, and the second additional protruding structures 322 are made of the same materials.

In some embodiments, the additional protruding structures 320 and the second additional protruding structures 322 are made of thermal conductive materials. In some embodiments, the thermal conductive materials of the additional protruding structures 320 and the second additional protruding structures 322 include aluminum (Al), Al alloy, copper (Cu), Cu alloy, silver (Ag), Ag alloy, gold (Au), Au alloy, a combination thereof, or another applicable material. In some embodiments, the thermal conductive materials of the additional protruding structures 320 and the second additional protruding structures 322 have thermal conductivity in a range from about 200 W/m. K to about 2000 W/mK. In some embodiments, the additional protruding structures 320 and the second additional protruding structures 322 are formed by a deposition process, such as a chemical vapor deposition (CVD) process, or a physical vapor deposition (PVD) process. In some other embodiments, the additional protruding structures 320 and the second additional protruding structures 322 are formed by metal precision processing.

Afterwards, as shown in FIG. 14C, the semiconductor die 120 is bonded to a package substrate 360 through the conductive connectors 164, in accordance with some embodiments. The lid structure 310 is attached to the package substrate 360 by an adhesive 364. The additional protruding structures 320 and the second additional protruding structures 322 are encapsulated by the thermal conductive materials 325 to form the thermal interface material (TIM) structure 350 on the semiconductor die 120.

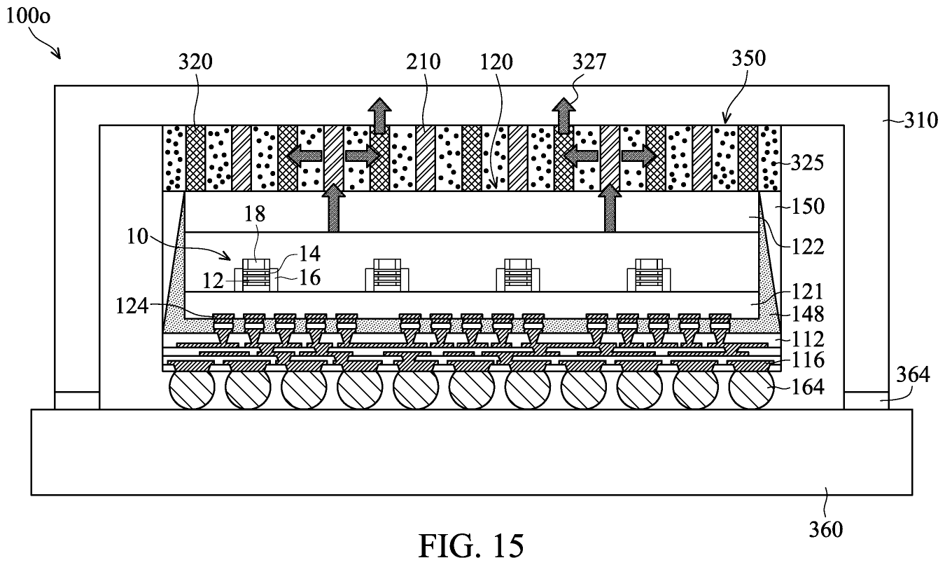

FIG. 15 shows a cross-sectional representation of a package structure 1000, in accordance with some embodiments of the disclosure. The package structure 1000 is similar to, or the same as, the package structure 100a shown in FIGS. 1A-1I. Processes and materials used to form package structure 1000 may be similar to, or the same as, those used to form the package structure 100a and a detailed description thereof is not repeated herein.

The difference between FIG. 15 and FIG. 1I is that the protruding structures 210 and the additional protruding structures 320 have the same height. In addition, the protruding structures 210 are in direct contact with the lid structure 310 and the substrate 122 of the semiconductor die 120. In other words, there is no gap between the top surface of the protruding structures 210 and the lid structure 310. There is no gap between the bottom surface of the additional protruding structures 320 and the substrate 122 of the semiconductor die 120.

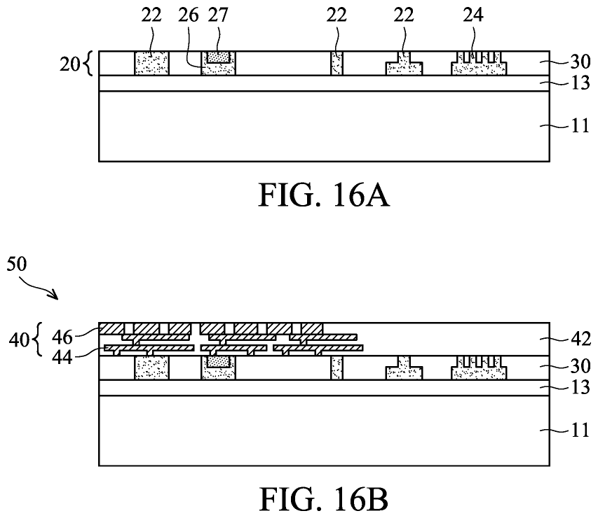

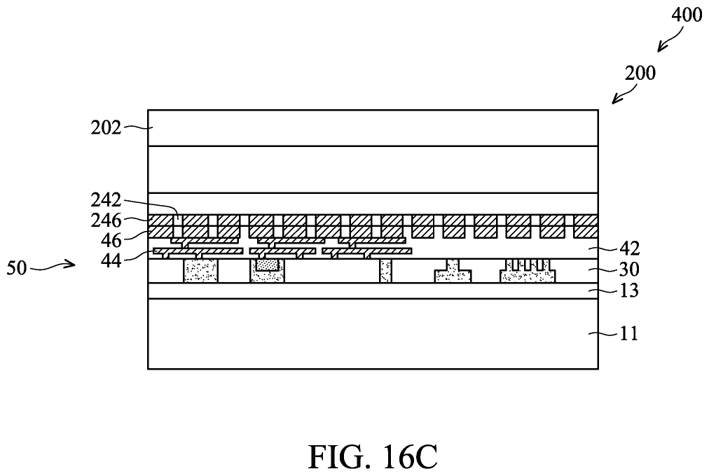

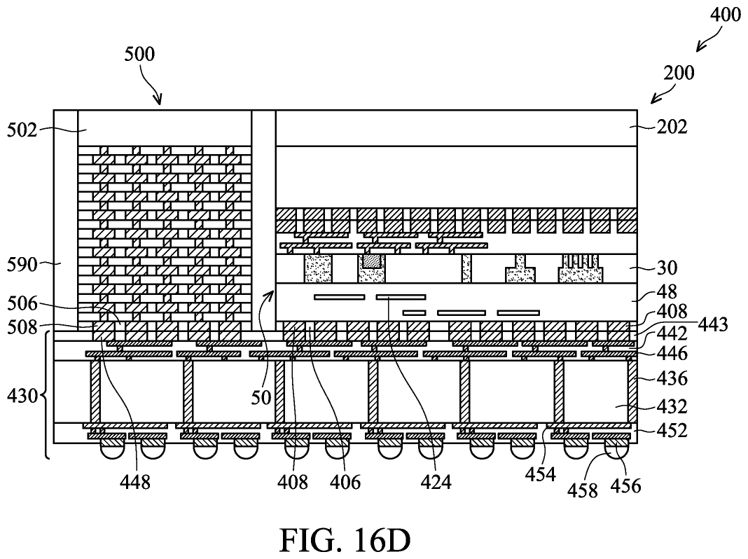

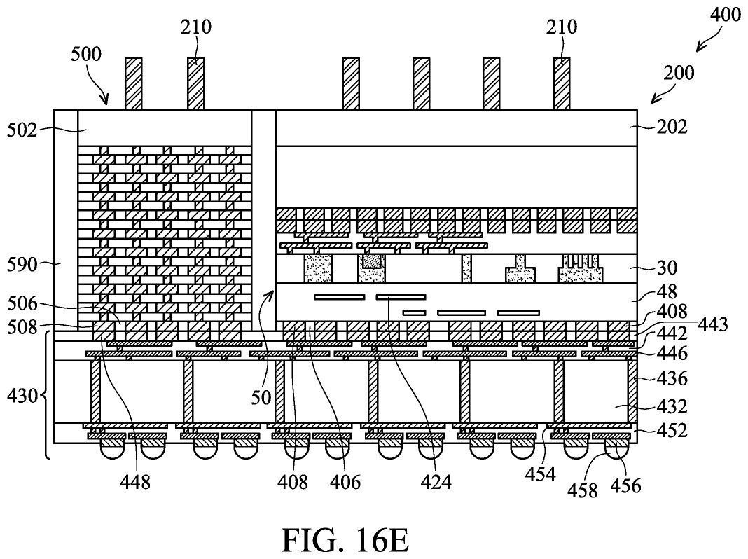

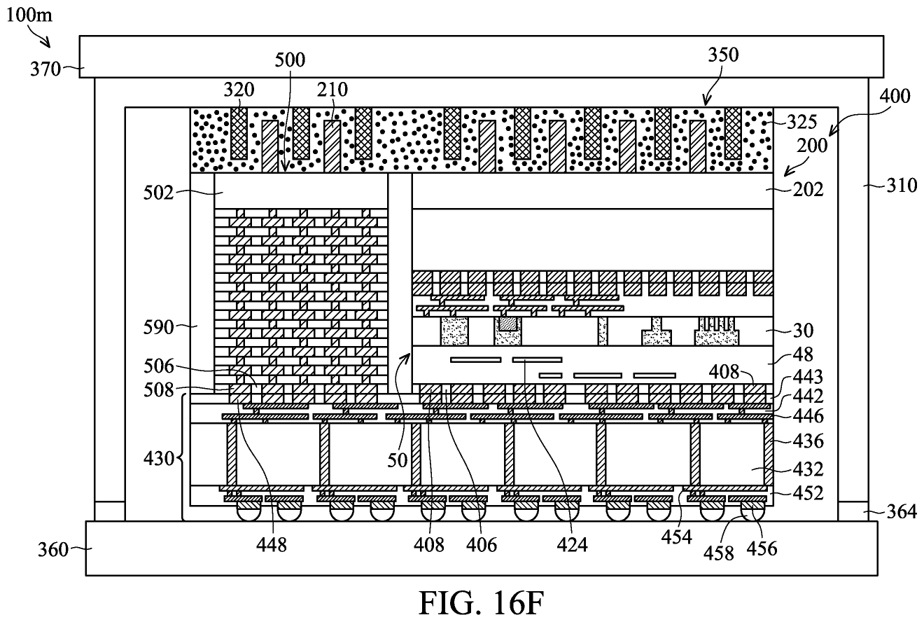

FIGS. 16A-16F show cross-sectional representations of various stages of forming a package structure 100m, in accordance with some embodiments of the disclosure.

As shown in FIG. 16A, an optical die 50 (seen in FIG. 16B) is formed by step FIG. 16A to FIG. 16B and includes forming a substrate 11, an insulator layer 13 and a silicon layer (not shown), in accordance with some embodiments. In some embodiments, the optical die 50 is an optical interposer. In some embodiments, the optical die 50 is in a wafer form.

The insulator layer 13 is formed over the substrate 11, and the silicon layer (not shown) is formed over the insulator layer 13. In some embodiments, the substrate 11, the insulator layer 13 and the silicon layer (not shown) are collectively be part of a silicon-on-insulator (SOI) substrate.

The substrate 11 may be a semiconductor wafer such as a silicon wafer. Alternatively or additionally, the substrate 11 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

The insulator layer 13 may be silicon oxide, silicon nitride, germanium oxide, germanium nitride, combinations of these, or another applicable material. In some embodiments, the insulator layer 13 is formed using thermal oxidation, chemical vapor deposition (CVD), atomic vapor deposition (ALD), physical vapor deposition (PVD), another suitable method, or a combination thereof.

Next, the silicon layer (not shown) is patterned to form optical components 20, in accordance with some embodiments. The various optical components 20 are used to form a photonic integrated circuit (PIC). The optical components 20 include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. The optical components 20 are formed by a patterning process. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process may include a dry etching process or a wet etching process.

In some embodiments, the optical components 20 include waveguides 22, couplers 24, modulators 26 and germanium modulator 27. The waveguides 22 is used to guide electromagnetic waves with minimal loss of energy by restricting the transmission of energy to two dimensions. In some embodiments, the multiple waveguides is formed and they are connected as a single continuous structure.

The couplers 24 may be integrated with the waveguides 22, and may be formed with the waveguides 22. The couplers 24 are photonic structures that allow optical signals and/or optical power to be transferred between the waveguides 22. In some embodiments, the couplers 24 include grating couplers, which allow optical signals and/or optical power to be transferred between the waveguides 22.

The modulators 26 are optically coupled to the waveguides 22 to receive electrical signals and generate corresponding optical signals within the waveguides 22 by modulating optical power within the waveguides 22. The modulators 26 may include the germanium modulator 27 over the modulators 26. In some embodiments, the germanium modulator 27 is formed by partially etching a portion of the silicon layer to form a recess and growing an epitaxial material in the recess on the remaining silicon layer. The silicon layer may be etched using photolithography and etching techniques. The epitaxial material may include a semiconductor material, such as doped or undoped germanium (Ge).

Although the configurations or arrangements of the optical component 20 including the waveguides 22, the couplers 24, the modulators 26 and the germanium modulator 27 are shown in FIG. 16A, the configurations or arrangements of optical component 20 may be adjusted according to actual application.

Afterwards, a dielectric layer 30 is formed on the optical component 20, in accordance with some embodiments. More specifically, the dielectric layer 30 is formed on the waveguides 22, the couplers 24, the modulators 26 and the germanium modulator 27. The dielectric layer 30 is used to separate the individual optical components 20.

In some embodiments, the dielectric layer 30 includes silicon oxide, silicon nitride, silicon oxynitride (SiON), or a combination thereof. In some embodiments, the dielectric layer 30 is formed using thermal oxidation, chemical vapor deposition (CVD), atomic vapor deposition (ALD), physical vapor deposition (PVD), another suitable method, or a combination thereof.

Next, as shown in FIG. 16B, an interconnect structure 40 is formed over the dielectric layer 30, in accordance with some embodiments. The interconnect structure 40 includes conductive layers 44 and conductive pads 46 embedded in a dielectric layer 42. The interconnect structure 40 may be used as a redistribution (RDL) structure for routing. Therefore, the optical die 50 is formed to have optical components 20 and interconnect structure 40 for connecting other dies or chips.

It should be noted that one or more optical components may be formed in the dielectric layer 42 of the interconnect structure 40. The optical components may include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like.

In some embodiments, the dielectric layer 42 include silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the dielectric layer 42 is formed using thermal oxidation, chemical vapor deposition (CVD), atomic vapor deposition (ALD), physical vapor deposition (PVD), another suitable method, or a combination thereof.

In some embodiments, the conductive layers 44 and the conductive pads 46 are made of conductive materials, such as copper (Cu), copper alloy, aluminum (Al), aluminum alloys, combinations thereof or another applicable material. In some embodiments, the conductive layers 44 and the conductive pads 46 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Afterwards, as shown in FIG. 16C, an electronic die 200 is bonded to the optical die 50, in accordance with some embodiments. The electronic die 200 includes a substrate 202. In some embodiments, the electronic die 200 is an electronic integrated circuit (EIC). The electronic die 200 includes conductive pads 246 embedded in dielectric layer 242 and the conductive pads 246 are for bonding to the interconnect structure 40.

The electronic die 200 may include integrated circuits for interfacing with the various photonic components formed in the dielectric layer 42 of the interconnect structure 40 or in the dielectric layer 30 of the optical die 50. The electronic die 200 is used to communicate with one or more of the optical components 20 (e.g., photonic components) in the optical die 50 using electrical signals.

In some embodiments, the electronic die 200 includes suitable device, such as a xPU, a logic die, a 3DIC die, a Central Processing Unit (CPU) die, a Graphic Processing Unit (GPU) die, a mobile application die, a Micro Control Unit (MCU) die, a BaseBand (BB) die, Application processor (AP), a SoC die, a MEMS die, or a combination thereof. Although one electronic die 200 is formed in FIG. 16C, two or more electronic dies may be bonded to the interconnect structure 40 in various embodiments.

Before the electronic die 200 and the optical die 50 are bonded together, a surface treatment is performed to active the surfaces of the conductive pads 246 and the conductive pads 46. In some embodiments, the surface treatment includes a dry treatment, a wet treatment, a plasma treatment, exposure to an inert gas, exposure to H₂, exposure to N₂, exposure to O₂, the like, or combinations thereof. After the surface treatment, a cleaning process is performed on the electronic die 200 and the optical die 50. Afterwards, the electronic die 200 and the optical die 50 are aligned, such that the conductive pads 246 of electronic die 200 can be bonded to the conductive pads 46 of the interconnect structure 40 of the optical die 50, and the dielectric layer 242 can be bonded to the dielectric layer 42 of the interconnect structure 40 of the optical die 50. In some embodiments, the alignment of the electronic die 200 and the optical die 50 may be achieved by using an optical sensing method.

After the alignment is performed, the electronic die 200 and the optical die 50 are bonded together by a hybrid bonding process. The hybrid bonding involves at least two types of bonding, including metal-to-metal bonding and dielectric-to-dielectric bonding. The electronic die 200 and the optical die 50 are hybrid bonded together by the application of pressure and heat.

Next, as shown in FIG. 16D, the substrate 11 and the insulator layer 13 are removed to expose the optical components 20, in accordance with some embodiments. Next, a dielectric layer 48 is formed on the exposed surface of the optical components 20, and the vias (not shown) are formed through the dielectric layer 30 and the dielectric layer 48. A composite die 400 includes the electronic die 200 and the optical die 50. The electronic die 200 is bonded to the optical die 50 by the hybrid bonding.

The composite die 400 further includes conductive pads 408 embedded in the bonding layer 406. Since the optical die 50 is formed below the electronic die 200, and the passage of the electrical signals and the optical signals are reduced and the transmission speed of the electrical signals and the optical signals are improved.

It should be noted that optical components 424 are formed in the dielectric layer 48 of the optical die 50 of the composite die 400. The optical components 424 include optical waveguides, couplers, optical switches, amplifiers, multiplexors, optical-to-electrical converters (e.g., P-N junctions), electrical-to-optical converters, combinations of these, or the like.

The optical components 424 are formed by a patterning process. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process may include a dry etching process or a wet etching process.

Next, an interposer 430 is formed, and the interposer 430 includes through vias (TVs) 436 are formed in the substrate 432. The interposer 430 further includes front side interconnect structure and a back-side interconnect structure. The front-side interconnect structure includes conductive layers 446 embedded in a dielectric layer 442. The conductive pads 448 are embedded in a bonding layer 443. The back-side interconnect structure includes conductive layers 454 embedded in a dielectric layer 452, and UBM layers 456 formed below the conductive layers 454, and conductive connectors 458 formed below the UBM layers 456.

The UBM layers 456 may contain an adhesion layer and/or a wetting layer. In some embodiments, the UBM layers 456 are made of titanium (Ti), titanium nitride (TiN), tantalum nitride (TaN), tantalum (Ta), or the like. In some embodiments, the UBM layers 156 further includes a copper seed layer. In some embodiments, the UBM layers 156 are formed by electroplating, electroless plating, printing, a chemical vapor deposition (CVD) process, a physical vapor process, or another applicable process.

After the interposer 430 is formed, the composite die 400 is bonded to the interposer 430. The conductive pads 408 of the composite die 400 are aligned with and bonded to the conductive pads 448 of the interposer 430 to form the metal-to-metal bonding, and the bonding layer 406 of the composite die 400 is aligned with and bonded to the bonding layer 443 of the interposer 430 to form the dielectric-to-dielectric bonding. As a result, the hybrid bonding structure having the metal-to-metal bonding and dielectric-to-dielectric bonding is formed between the composite die 400 and the interposer 430.

Next, a stacked die 500 is provided. The stacked die 500 may be a memory die, such as a static random access memory (SRAM) device, a dynamic random access memory (DRAM) device, a high bandwidth memory (HBM) device or another memory device.

The stacked die 500 includes substrate 502 and conductive pads 508 embedded in the bonding layer 506. The substrate 502 may include memory dies in the form of a die stack. The conductive pads 508 of the stacked die 500 are aligned with the conductive pads 448 of the interposer 430, and the bonding layer 506 of the stacked die 500 is aligned with the bonding layer 443 to form the hybrid bonding structure between the stacked die 500 and the interposer 430.

After the composite die 400 and the stacked die 500 are bonded to the interposer 430, a package layer 590 is formed to surround the composite die 400 and the stacked die 500.

Afterwards, as shown in FIG. 16E, a number of the protruding structures 210 are formed on the substrate 502 of the stacked die 500 and the substrate 202 of the electronic die 200, in accordance with some embodiments of the disclosure. The protruding structures 210 are formed on the substrate 202 and in direct contact with the substrate 202 of the electronic die 200.

Next, as shown in FIG. 16F, the lid structure 310 is provided, and a number of the additional protruding structures 320 are formed below the lower surface of the lid structure 310, in accordance with some embodiments of the disclosure. Next, the protruding structures 210, and the additional protruding structures 320 are encapsulated by the thermal conductive materials 325 to form the thermal interface material (TIM) structure 350, in accordance with some embodiments of the disclosure.

It should be noted that the heat generated by the composite die 400 and the stacked die 500 can be transferred to the external environment by the protruding structures 210 and the additional protruding structures 320 in the thermal interface material (TIM) structure 350.

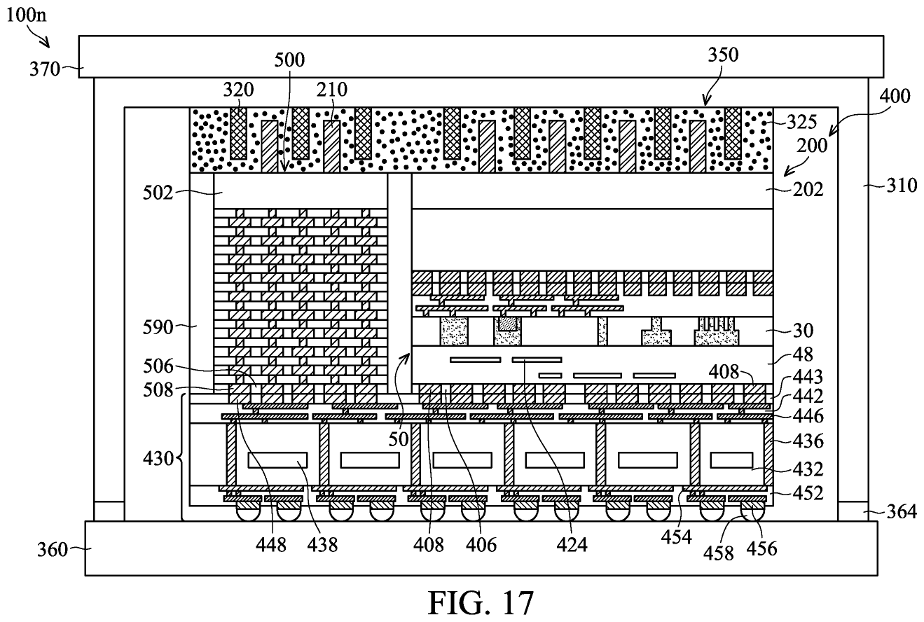

FIG. 17 illustrates a cross-sectional representation of a package structure 100n, in accordance with some embodiments. The package structure 100n is an alternate embodiment which may be similar to the package structure 100m of FIG. 16F, where like reference numerals indicate like elements formed using like processes, unless specified otherwise. Processes and materials used to form the package structure 100n may be similar to, or the same as, those used to form the package structure 100m and are not repeated herein.

The difference between FIG. 17 and FIG. 16F is that local silicon interconnect (LSI) dies 438 are formed in the substrate 432. The LSI dies 438 may be encapsulated in an encapsulant. A number of Through-vias (not shown) may be formed to penetrate through the encapsulant.

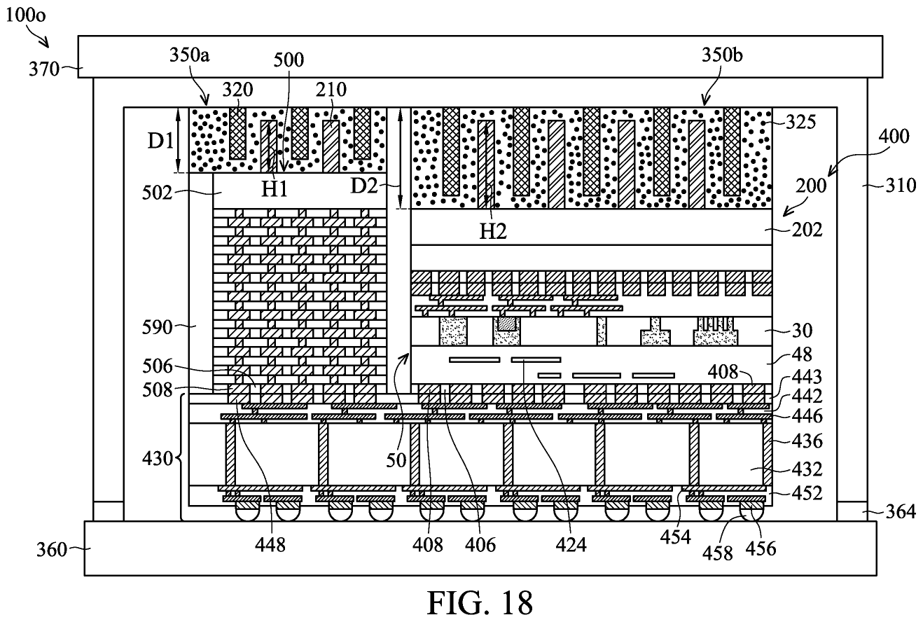

FIG. 18 shows a cross-sectional representation of a package structure 1000, in accordance with some embodiments of the disclosure. The package structure 1000 is similar to, or the same as, the package structure 100m shown in FIG. 16F. Processes and materials used to form package structure 1000 may be similar to, or the same as, those used to form the package structure 100m and a detailed description thereof is not repeated herein.

The difference between FIG. 18 and FIG. 16F is that the first portions 350a of the thermal interface material (TIM) structure 350 is formed on the stacked die 500, and the second portion 350b of the thermal interface material (TIM) structure 350 is formed on the composite die 400. The first portion 350a of the thermal interface material (TIM) structure 350 is separated from the second portion 350b of the thermal interface material (TIM) structure 350 by the air.

As shown in FIG. 18, each of the protruding structures 210 directly above the stacked die 500 has a first height H1 along the vertical direction. Each of the protruding structures 210 directly above the composite die 400 has a second height H₂ along the vertical direction. In some embodiments, the second height H₂ is greater than the first height H1.

The first portion 350a of the thermal interface material (TIM) structure 350 has a first thickness D1 along the vertical direction, and the second portion 350b of the thermal interface material (TIM) structure 350 has a second thickness D2 along the vertical direction. In some embodiments, the second thickness D2 is greater than the first thickness D1.

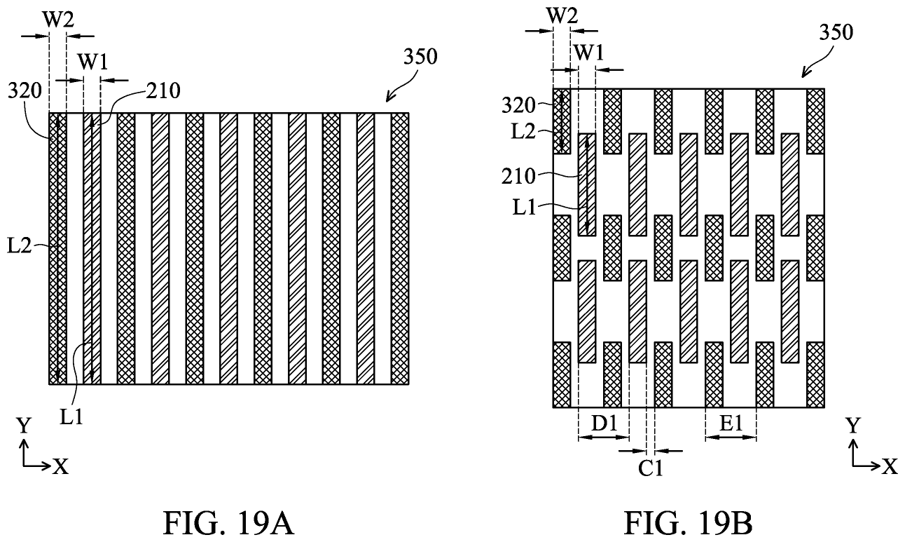

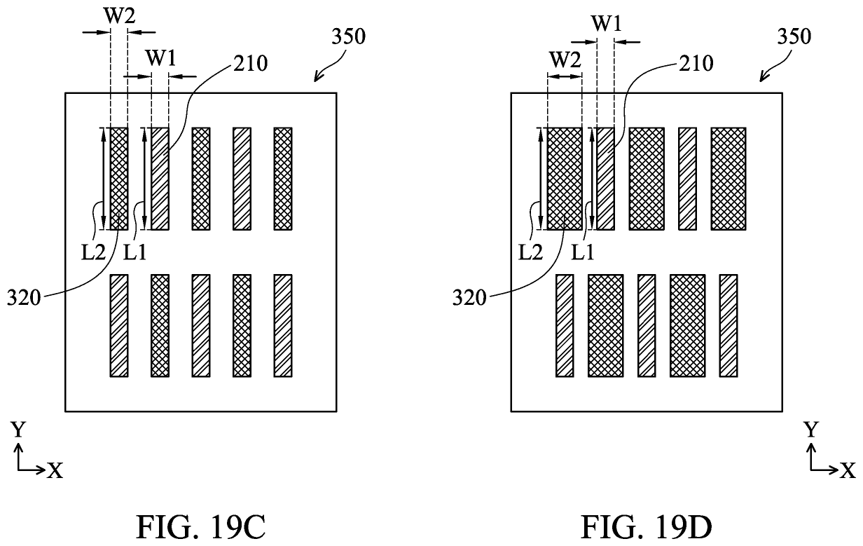

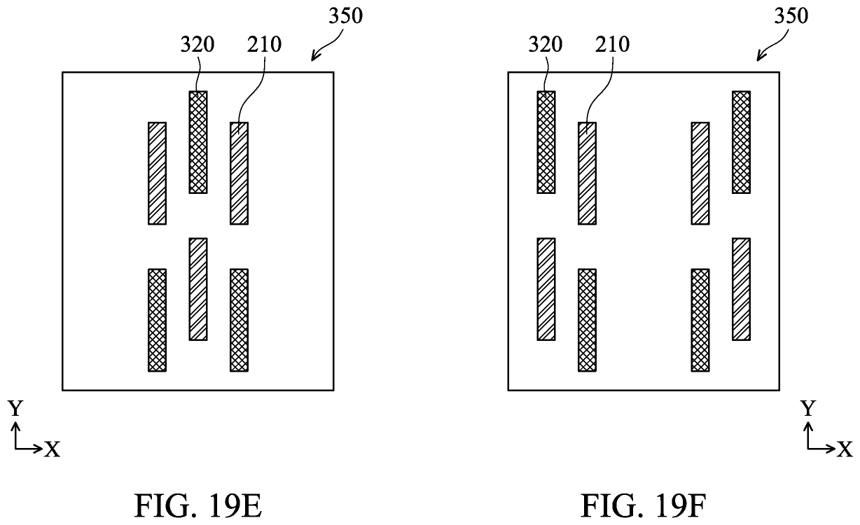

FIGS. 19A-19F show the top views of the protruding structures 210 and the additional protruding structures 320 of the thermal interface material (TIM) structure 350, in accordance with some embodiments of the disclosure.

As shown in FIG. 19A, the protruding structures 210 and the additional protruding structures 320 are alternatively arranged. Each of the protruding structures 210 has a first with W1 along the first direction (e.g. X-axis) and a first length L1 along the second direction (e.g. Y-axis). Each of the additional protruding structures 320 has a second with W2 along the first direction (e.g. X-axis) and a second length L2 along the second direction (e.g. Y-axis). In some embodiments, the first width W1 of the protruding structure 210 is substantially equal to the second width W2 of the additional protruding structure 320. In some embodiments, the first length L1 of the protruding structure 210 is substantially equal to the second length L2 of the additional protruding structure 320.

As shown in FIG. 19B, the first width W1 of the protruding structure 210 is substantially equal to the second width W2 of the additional protruding structure 320. In some embodiments, the first length L1 of the protruding structure 210 is greater than the second length L2 of the additional protruding structure 320.

There is a distance C1 between a left sidewall surface of the protruding structure 210 and a left sidewall surface of the adjacent protruding structure 210. In some embodiments, the distance C1 is in a range from about 5 micrometer (μm) to about 50 micrometer (μm).

There is a distance D1 between a right sidewall surface of the additional protruding structure 320 and a left sidewall surface of the protruding structure 210. In some embodiments, the distance D1 is in a range from about 5 micrometer (μm) to about 400 micrometer (μm).

There is a distance E1 between a left sidewall surface of the additional protruding structure 320 and a left sidewall surface of the adjacent additional protruding structure 320. In some embodiments, the distance E1 is in a range from about 5 micrometer (μm) to about 400 micrometer (μm).

As shown in FIG. 19C, the protruding structures 210 and the additional protruding structures 320 are alternatively arranged in the first direction (e.g. X-axis) and in the second direction (e.g. Y-axis).

As shown in FIG. 19D, the size of the additional protruding structures 320 is greater than the size of the protruding structures 210. In some embodiments, the first width W1 of the protruding structure 210 is smaller than the second width W2 of the additional protruding structure 320.

As shown in FIG. 19E, the protruding structures 210 and the additional protruding structures 320 are alternatively arranged and mainly disturbed at the central portion of the thermal interface material (TIM) structure 350 when the hot spots are located at the central portion of the die.

As shown in FIG. 19F, the protruding structures 210 and the additional protruding structures 320 are alternatively arranged and mainly disturbed at peripheral portion of the thermal interface material (TIM) structure 350 when the hot spots are located at the peripheral portion of the die.

In some embodiments, the protruding structures 210 are formed on the semiconductor die 120 and the stacked die 130 to help the heat dissipation efficiency. The additional protruding structures 320 are formed below the lid structure 310 to help the heat dissipation efficiency. The heat generated by the semiconductor die 120 and the stacked die 130 can be transferred horizontally and vertically to the external environment through the stacked alternating protruding structures. In some embodiments, the semiconductor die 120 is a logic die, and the stacked die 130 is a memory die.

In some embodiments, the protruding structures 210 are formed on the composite die 400 with the electronic die 200 and the optical die 50. Since the optical die 50 is formed below the electronic die 200, the passage of the electrical signals and the optical signals are reduced and the transmission speed of the electrical signals and the optical signals are improved.

Embodiments for forming a package structure and method for formation the same are provided. The package structure includes a die formed over a substrate. The protruding structures are formed on and thermally connected to the die. A lid structure with protruding structures is provided, and the protruding structures are thermally connected to the lid structure. The lid structure is disposed over the die, and a thermal interface material (TIM) structure is constructed by the protruding structures formed on the die and the protruding structures formed below the lid structure. The heat or thermal energy generated by the die can be transferred to the external environment by the protruding structures in the TIM. The stacked alternating protruding structures in the TIM are configured to improve the heat dissipation efficiency. Therefore, the power efficiency and the performance of the package structure are increased.

In some embodiments, a package structure is provided. The package structure includes a first die over a substrate, and a lid structure over the first die. The package structure also includes a thermal interface material structure between the first die and the lid structure. The thermal interface material structure comprises a plurality of protruding structures connected to the first die, a plurality of additional protruding structures connected to the lid structure and a thermal conductivity material between the protruding structures and the additional protruding structures.

In some embodiments, a package structure is provided. The package structure includes a first die and a second die over a substrate, and a top surface of the first die is higher than a top surface of the second die. The package structure includes a plurality of first protruding structures extending upwardly from the first die, and a plurality of second protruding structures extending upwardly from the second die. The package structure includes a lid structure on the first die and the second die. The package structure also includes a plurality of additional protruding structures extending downwardly from the lid structure, and the first protruding structures, the second protruding structures and the additional protruding structures are encapsulated by a thermal conductivity material to form a thermal interface material structure.

In some embodiments, a method for forming a package structure is provided. The method includes forming a first die on a substrate, and forming a plurality of protruding structures on the first die. The method includes disposing a lid structure over the first die, and forming a plurality of additional protruding structures below the lid structure, wherein the plurality of protruding structures are in parallel with the plurality of additional protruding structures. The method includes forming a thermal interface material structure between the first die and the lid structure, and the plurality of protruding structures and the plurality of additional protruding structures are encapsulated by a thermal conductivity material to form the thermal interface material structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first die over a substrate;
a lid structure over the first die; and
a thermal interface material structure between the first die and the lid structure, wherein the thermal interface material structure comprises:
a plurality of protruding structures connected to the first die;
a plurality of additional protruding structures connected to the lid structure; and
a thermal conductivity material between the protruding structures and the additional protruding structures.

2. The package structure as claimed in claim 1, wherein the protruding structures and the additional protruding structures are alternatively stacked.

3. The package structure as claimed in claim 1, further comprising:
an external cooling unit formed on the lid structure, wherein the first die is thermally connected to the external cooling unit by the thermal interface material structure.

4. The package structure as claimed in claim 1, further comprising:
a second die adjacent to the first die, wherein the protruding structures are connected to the second die.

5. The package structure as claimed in claim 1, further comprising:
a second die adjacent to the first die; and
second protruding structures connected to the second die, wherein the thermal interface material structure further comprises the second protruding structures.

6. The package structure as claimed in claim 5, wherein each of the protruding structures has a first height, each of the second protruding structures has a second height, and the second height is greater than the first height.

7. The package structure as claimed in claim 5, wherein the thermal interface material structure has a first portion between the protruding structures and the additional protruding structures, and a second portion between the second protruding structures and the additional protruding structures, wherein the first portion has a first thickness, the second portion has a second thickness, and the second thickness is greater than the first thickness.

8. The package structure as claimed in claim 1, wherein the first die comprises a plurality of memory dies, and an additional substrate over the memory dies, and the protruding structures are formed on the additional substrate of the first die.

9. The package structure as claimed in claim 1, wherein the first die comprises an electronic die and an optical die, and the optical die comprises an optical component.

10. A package structure, comprising:
a first die and a second die over a substrate, wherein a top surface of the first die is higher than a top surface of the second die;
a plurality of first protruding structures extending upwardly from the first die;
a plurality of second protruding structures extending upwardly from the second die
a lid structure on the first die and the second die; and
a plurality of additional protruding structures extending downwardly from the lid structure, wherein the first protruding structures, the second protruding structures, and the additional protruding structures are encapsulated by a thermal conductivity material to form a thermal interface material structure.

11. The package structure as claimed in claim 10, wherein each of the first protruding structures has a first height, each of the second protruding structures has a second height, and the second height is greater than the first height.

12. The package structure as claimed in claim 10, wherein the thermal interface material structure has a first portion and a second portion, and the first portion is separated from the second portion by air.

13. The package structure as claimed in claim 10, wherein the first die comprises a plurality of memory dies, and the second die comprises an electronic die and an optical die.

14. The package structure as claimed in claim 10, further comprising:
an interposer between the first die and the substrate, wherein the interposer comprises an optical component.

15. The package structure as claimed in claim 10, further comprising:
an interposer between the first die and the substrate, wherein the interposer comprises a plurality of local silicon interconnect (LSI) dies.

16. A method for forming a package structure, comprising:
forming a first die on a substrate;
forming a plurality of protruding structures on the first die;
disposing a lid structure over the first die;
forming a plurality of additional protruding structures below the lid structure, wherein the plurality of protruding structures are in parallel with the plurality of additional protruding structures; and
forming a thermal interface material structure between the first die and the lid structure, wherein the plurality of protruding structures and the plurality of additional protruding structures are encapsulated by a thermal conductivity material to form the thermal interface material structure.

17. The method for forming the package structure as claimed in claim 16, further comprising:
forming an interposer between the first die and the substrate, wherein the interposer comprises a plurality of optical components.

18. The method for forming the package structure as claimed in claim 16, wherein the first die comprises an electronic die and an optical die, and a hybrid bonding structure between the electronic die and the optical die.

19. The method for forming the package structure as claimed in claim 16, wherein the thermal interface material structure has a first portion and a second portion, and the first portion is separated from the second portion by air.

20. The method for forming the package structure as claimed in claim 16, further comprising:
forming an external cooling unit on the lid structure, wherein the first die is thermally connected to the external cooling unit by the thermal interface material structure.
